(19) United States
(12) Patent Application Publication
(10) Pub. No.: US 2026/0016753 A1
(43) Pub. Date: Jan. 15, 2026

(54) SUBSTRATE PROCESSING SYSTEM, SUBSTRATE PROCESSING METHOD, AND RECORDING MEDIUM

(71) Applicant: Tokyo Electron Limited, Tokyo (JP)

(72) Inventors: Satoru SHIMURA, Koshi City (JP); Kosuke YOSHIHARA, Koshi City (JP); Arnaud Alain Jean DAUENDORFFER, Koshi City (JP)

(73) Assignee: Tokyo Electron Limited, Tokyo (JP)

(21) Appl. No.: 19/266,374

(22) Filed: Jul. 11, 2025

(30) Foreign Application Priority Data
Jul. 12, 2024 (JP) 2024-112225

(51) Int. Cl. G03F 7/16; B08B 9/00; C23C 16/40; C23C 16/44; C23C 16/458; C23C 16/46; C23C 16/56; G03F 7/004

(52) U.S. Cl. CPC G03F 7/167; B08B 9/00; C23C 16/40; C23C 16/4405; C23C 16/4586; C23C 16/46; C23C 16/56; G03F 7/0043; G03F 7/168

(57) ABSTRACT

A substrate processing system includes a first processing vessel forming a first processing space and a second processing vessel forming a second processing space, each processing space being for storing a substrate; an atmosphere adjuster for setting an adjustment area into a second atmosphere, the second atmosphere having an oxygen concentration and a humidity lower than those of a first atmosphere at an outside of the adjustment area and having a pressure equal to or close to a pressure of the outside of the adjustment area; a resist film former having the first processing vessel and supplying a resist component-containing gas into the first processing space under the second atmosphere to form a resist film on the substrate; and a heater having the second processing vessel and heating, under the second atmosphere, the substrate before being subjected to exposure of the resist film.

### CROSS-REFERENCE TO RELATED APPLICATION

This application claims the benefit of Japanese Patent Application No. 2024-112225 filed on Jul. 12, 2024, the entire disclosures of which are incorporated herein by reference.

### TECHNICAL FIELD

The various aspects and embodiments described herein pertain generally to a substrate processing system, a substrate processing method, and a recording medium.

### BACKGROUND

A manufacturing process of a semiconductor device includes photolithography, which involves forming a resist film on a substrate such as a semiconductor wafer (hereinafter, simply referred to as a wafer) and performing patterning. Patent Document 1 describes forming the resist film by supplying a gas in a vacuum atmosphere.
Patent Document 1: Japanese Patent-Laid open Publication No. 2022-538554

### SUMMARY

In an exemplary embodiment, a substrate processing system includes a first processing vessel forming a first processing space and a second processing vessel forming a second processing space, each processing space being for storing a substrate; an atmosphere adjusting mechanism configured to set an adjustment area including the first processing space and the second processing space into a second atmosphere, the second atmosphere having an oxygen concentration and a humidity lower than those of a first atmosphere at an outside of the adjustment area and having a pressure equal to or close to a pressure of the outside of the adjustment area; a resist film forming device having the first processing vessel, the resist film forming device being configured to supply a resist component-containing gas into the first processing space under the second atmosphere to form a resist film on the substrate; and a heat treating device having the second processing vessel, the heat treating device being configured to heat, under the second atmosphere, the substrate before being subjected to exposure of the resist film.

### BRIEF DESCRIPTION OF THE DRAWINGS

FIG. 1 is a plan view of a wafer processing system according to a first exemplary embodiment of the present disclosure;

FIG. 2 is a longitudinal front view of the wafer processing system;

FIG. 3 is a longitudinal side view of the wafer processing system;

FIG. 4 is a longitudinal side view of a resist film forming device in the wafer processing system;

FIG. 5 is a longitudinal side view of a heat treating device for PAB (Pre Apply Bake) in the wafer processing system;

FIG. 6 is an explanatory diagram illustrating an operation of the resist film forming device;

FIG. 7 is an explanatory diagram illustrating the operation of the resist film forming device;

FIG. 8 is an explanatory diagram illustrating the operation of the resist film forming device;

FIG. 9 is an explanatory diagram illustrating the operation of the resist film forming device;

FIG. 10 is a longitudinal side view illustrating a first modification example of the resist film forming device;

FIG. 11 is a schematic diagram illustrating a longitudinal side of a wafer;

FIG. 12 is a schematic diagram illustrating the longitudinal side of the wafer;

FIG. 13 is a schematic diagram illustrating the longitudinal side of the wafer;

FIG. 14 is a longitudinal side view illustrating a first modification example of the heat treating device;

FIG. 15 is a longitudinal side view illustrating a second modification example of the resist film forming device;

FIG. 16 is a graph showing a temperature variation of the wafer;

FIG. 17 is a plan view of a wafer processing system according to a second exemplary embodiment;

FIG. 18 is a longitudinal side view of the wafer processing system according to the second exemplary embodiment;

FIG. 19 is a plan view of a wafer processing system according to a third exemplary embodiment;

FIG. 20 is a perspective view illustrating a buffer device provided in the wafer processing system according to the third exemplary embodiment;

FIG. 21 is a perspective view of the buffer device;

FIG. 22 is a perspective view of the buffer device;

FIG. 23A to FIG. 23C are schematic longitudinal side views of the buffer device;

FIG. 24 is a longitudinal side view of a wafer processing system according to a fourth exemplary embodiment; and

FIG. 25 is a plan view of a wafer processing system according to a fifth exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

### First Exemplary Embodiment

Hereinafter, a wafer processing system as a substrate processing apparatus according to a first exemplary embodiment will be described with reference to the accompanying drawings. In the present specification and the drawings, parts having substantially the same functions and configurations will be assigned same reference numerals, and redundant descriptions thereof will be omitted.

### <Wafer Processing System>

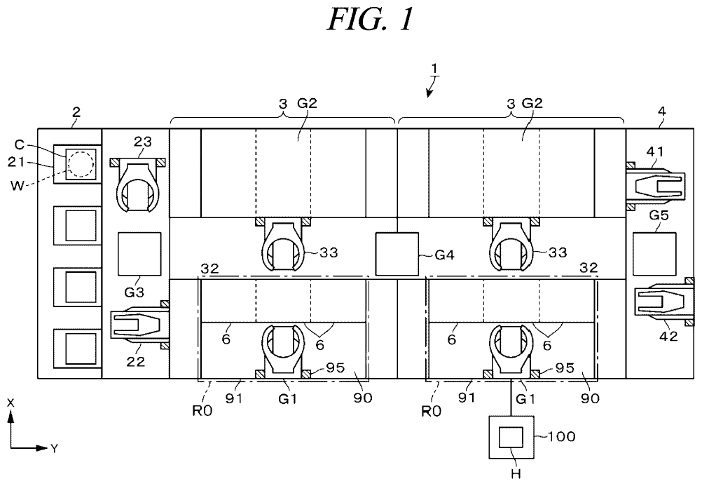

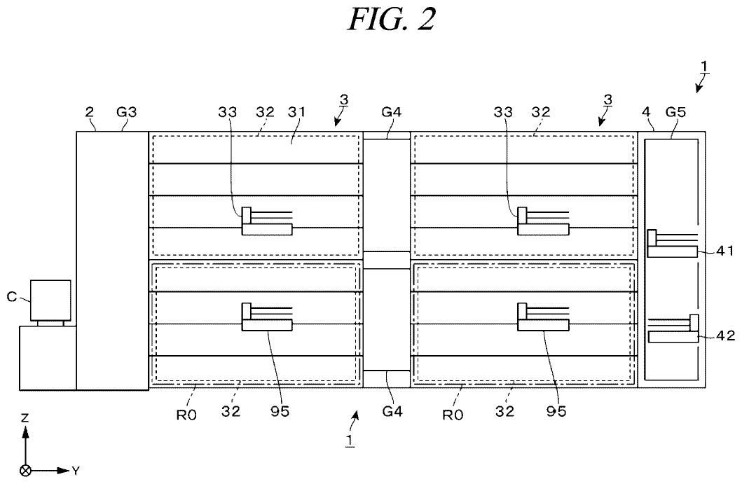

First, a configuration of the wafer processing system according to the present exemplary embodiment will be explained. FIG. 1 and FIG. 2 are a plan view and a front view, respectively, showing a schematic configuration of a wafer processing system 1. The present exemplary embodiment will be explained for an example where the wafer processing system 1 is configured as a photolithography processing system that performs a resist film forming process and a developing process on a wafer W.

The wafer processing system 1, which is a substrate processing system, has, as shown in FIG. 1, a cassette station 2 in which a cassette C accommodating a multiple number of wafers W is carried in and out, and a processing station 3 equipped with a plurality of various types of processing devices each configured to perform a preset processing on the wafers W. The wafer processing system 1 has a configuration in which the cassette station 2, the processing station 3, and an interface station 4 configured to transfer the wafers W to/from an exposure device (not shown) adjacent to the opposite side of the processing station 3 are connected as a single structure. Here, two processing stations 3 are disposed between the cassette station 2 and the interface station 4, as shown in FIG. 1, but one or more than two processing stations 3 may be provided.

The cassette station 2 is provided with a plurality of cassette placement tables 21 and wafer transfer devices 22 and 23. The cassette station 2 is configured to transfer wafers between the cassette C placed on the cassette placement table 21 and the processing station 3 by the wafer transfer device 22 or 23. For this purpose, the wafer transfer device 22 (23) is equipped with a driving mechanism having a movement path in various directions such as horizontal directions (X-axis direction and Y-axis direction), a vertical direction (Z-axis direction), and around a vertical axis (0 direction), as necessary, or may be equipped with a driving mechanism having movement paths in all directions.

At least one of the wafer transfer devices 22 and 23 is capable of delivering the wafer to and from the cassette C, and is also capable of performing a wafer delivery operation with respect to the processing station 3. Here, the wafer delivery operation with respect to the processing station 3 means, by way of example, delivering the wafer to/from a third block G3 that is equipped with a delivery device accessible by a wafer transfer device 33 inside the processing station 3 to be described below. The third block G3 may include multiple delivery devices (not shown) arranged in a vertical direction.

An inspection device (not shown) for inspecting the wafer W may be provided at a location accessible by either one of the wafer transfer devices 22 and 23.

The processing station 3 is provided with a plurality of, for example, three blocks: first, second and fourth blocks G1, G2, and G4. As shown in FIG. 2, multiple layers 31 including the first and second blocks G1 and G2 are stacked vertically. By way of example, the first block G1 is provided on the front side (negative X-axis side of FIG. 1) of the processing station 3, and the second block G2 is provided on the rear side (positive X-axis side of FIG. 1) of the processing station 3. The fourth block G4 is provided on the interface station 4 side (positive Y-axis side of FIG. 1) of the processing station 3 or at a connection portion with another adjacent processing station 3. The fourth block G4 may have multiple delivery devices arranged in a vertical direction. Further, the aforementioned third block G3 may be provided in the processing station 3.

The first block G1 is provided with multiple processing devices, such as a patterning film forming device and a developing device, both of which are not shown. The patterning film forming device may include, for example, a resist film forming device and an anti-reflection film forming device. By way of example, multiple processing devices are arranged in a horizontal direction. Here, the number, layout and type of these processing devices may be selected as required.

In these patterning film forming device and developing device, a preset processing liquid or a preset gas is supplied onto the wafer W. In this way, in the patterning film forming device, a resist film to be used as a mask when forming a pattern of a film in an underneath layer is formed, or an anti-reflection film for efficiently performing a light radiation process, such as an exposure process, is formed. In the developing device, a part of the exposed resist film is removed to form an irregularity pattern as the mask. In the present specification, various kinds of gases supplied in the patterning film forming device and the developing device may be mist in addition to gaseous fluids.

For example, in the second block G2, heat treating devices (not shown) each configured to perform a heat treatment such as heating or cooling of the wafer W are provided in both a vertical direction and a horizontal direction. In addition, although not shown, a hydrophobizing device configured to perform a hydrophobization processing to improve fixation of the resist and the wafer W, and a peripheral exposure device configured to expose a peripheral portion of the wafer W are also provided in a vertical direction (Z-axis direction in FIG. 2) and a horizontal direction. The number and layout of these heat treating devices, hydrophobizing devices, and peripheral exposure devices may be selected as required.

As shown in FIG. 1, a wafer transfer area 32 is formed in an area between the first block G1 and the second block G2 when viewed from the top. In the wafer transfer area 32, the wafer transfer device 33, for example, is disposed.

The wafer transfer device 33 has a transfer arm 92 configured to be movable in, the Y-axis direction, a forward/backward direction, the 0 direction, and a vertical direction, for example. The wafer transfer device 33 moves in the wafer transfer area 32 and is able to transfer the wafer W to a predetermined device in the first block G1, the second block G2, the third block G3, or the fourth block G4 around it. When there are the multiple processing stations 3 as shown in FIG. 1, the wafer transfer device 33 provided in the processing station 3 located on the interface station 4 side can transfer the wafer W to a preset device in a fifth block G5 to be described below as well as to the first, second, and fourth blocks G1, G2, and G4.

The wafer transfer device 33 includes multiple wafer transfer devices, and they are arranged vertically as shown in FIG. 2, for example. One wafer transfer device 33 is capable of transferring the wafers W to preset devices located at heights of a plurality of layers 31 at an upper side among the multiple layers 31 stacked vertically. Another wafer transfer device 33 may transfer the wafers W to preset devices located at heights of a multiplicity of layers 31 located below the plurality of layers 31. Multiple wafer transfer areas 32 are provided to enable such transfer of the wafers W. Here, the number of the wafer transfer devices 33 and the number of the layers 31 corresponding to one wafer transfer device 33 may be selected as required. By way of example, the wafer transfer device 33 may be provided for each layer 31.

In addition, the wafer transfer area 32, the first block G1, or the second block G2 may have a shuttle transfer device (not shown). The shuttle transfer device transfers the wafer W linearly between a space adjacent to one side of the processing station 3 and another space adjacent to the opposite side of the processing station 3.

The interface station 4 is provided with the fifth block G5 having multiple delivery devices, and wafer transfer devices 41 and 42. The interface station 4 transfers the wafer W between the fifth block G5, to which the wafer W is transferred by the wafer transfer device 33, and the exposure device, using the wafer transfer device 41 or 42. For this purpose, the wafer transfer device 41 (42) is equipped with driving mechanism respectively having movement paths in respective directions, such as horizontal directions (X-axis direction and Y-axis direction), a vertical direction (Z-axis direction), and around a vertical axis (θ direction), as necessary, or may have a driving mechanism having movement paths in all directions. At least one of the wafer transfer devices 41 and 42 is capable of supporting the wafer W and transferring it between the transfer device of the fifth block G5 and the exposure device.

A cleaning device for cleaning a surface of the wafer W and the aforementioned peripheral exposure device may be provided at positions inside the interface station 4 that are accessible by either one of the wafer transfer devices 41 and 42.

The inspection device may be provided in the cassette station 2 as mentioned above. Alternatively, however, the inspection device may also be provided in the processing station 3 (the interface station 4) at a position accessible by any one transfer arm 33 (41 or 42) (see FIG. 1 or FIG. 2) provided inside it.

The above-described wafer processing system 1 is provided with a control device 100 as a controller. The control device 100 is, for example, a computer, and has a program storage (not shown). The program storage stores a program for controlling the processing of the wafer W in the wafer processing system 1. The program storage also stores a program for controlling the operations of the driving systems such as the above-described various transfer devices and processing devices to implement the wafer processing in the wafer processing system 1. The program includes process groups required to perform the transfer and the processing of the wafer W in the wafer processing system 1, and the control device 100 outputs control signals to the individual components of the wafer processing system 1 according to the program to control the individual components as stated above, thereby implementing the above-described transfer and processing of the wafer W. The programs may have been recorded in a computer-readable recording medium H, and may be installed from the recording medium H into the control device 100. The recording medium H may include a ROM, a RAM, or a hard disk, but the structure and type of the recording medium H may not be particularly limited, and it may be transitory or non-transitory. Further, the control device 100 may include parts for storing, reading, and executing the programs for implementing the wafer processing as well as a part for performing communication related thereto, and these individual parts may be located either inside or outside the wafer processing system 1. The control device 100 may be one or multiple circuits, and may be provided as an integrated whole or in a partially divided form. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

### <Operation of Wafer Processing System>

The wafer processing system 1 is configured as described above. Now, an example of the wafer processing performed by using the wafer processing system 1 having the above-described configuration will be explained.

First, the cassette C accommodating the multiple number of wafers W is carried into the cassette station 2 of the wafer processing system 1 and placed on the cassette placement table 21. Next, each wafer W in the cassette C is sequentially taken out by the wafer transfer device 22 or 23 and transferred to the delivery device in the third block G3.

The wafer W transferred to the delivery device of the third block G3 is supported by the wafer transfer device 33 and transferred to the hydrophobizing device provided in the second block G2, where a hydrophobization processing is performed. Subsequently, the wafer W is transferred to the resist film forming device by the wafer transfer device 33, where a resist film is formed on the wafer W, then transferred to the heat treating device to be subjected to pre-bake, and then transferred to the delivery device of the fifth block G5. Further, when there are the multiple processing stations 3 as in FIG. 1 and FIG. 2, the wafer W is once placed in the delivery device of the fourth block G4 before being transferred to the delivery device of the fifth block G5, and then transferred to the multiple wafer transfer devices 33. In addition, when necessary, the wafer W may be transferred to the peripheral exposure device by the wafer transfer device 33, where an exposure processing may be performed on the peripheral portion of the wafer W. The processing from the formation of the resist film to the pre-bake will be explained later in detail.

The wafer W transferred to the delivery device of the fifth block G5 is transferred to the exposure device by the wafer transfer device 41 or 42 to be exposed into a preset pattern. The wafer W may be cleaned by the cleaning device before being subjected to the exposure processing.

The exposed wafer W is transferred to the delivery device of the fifth block G5 by the wafer transfer device 41 or 42. Thereafter, the wafer W is transferred to the heat treating device by the wafer transfer device 33 to be subjected to post-exposure bake.

The wafer W after being subjected to the post-exposure bake is transferred to the developing device by the wafer transfer device 33 to be developed. Upon the completion of the development, the wafer W is transferred to the heat treating device by the wafer transfer device 33 to be subjected to post-bake.

The wafer W is then transferred by the wafer transfer device 33 to the delivery device of the third block G3, and transferred by the wafer transfer device 22 or 23 in the cassette station 2 to the cassette C on the preset cassette placement table 21. In this way, the series of photolithography processes are completed.

The wafer processing system in the present disclosure is not limited to the configuration and operation described above. By example, in the above-described exemplary embodiment, the wafer processing system is directly connected to the exposure device and transfers the wafer W between the interface station 4 and the exposure device, but the wafer processing system does not need to be directly connected to the exposure device. For example, in such a case, the wafer W is transferred from the cassette station 2 to the processing station 3, where a necessary processing is performed, and then transferred back to the cassette station 2 to be taken out of the system. Further, an unnecessary processing device among the processing devices mentioned above may be omitted from the wafer processing system, or the processing in that unnecessary processing device may not be performed.

### [MOR]

The wafer processing system 1 is placed in a clean room in a semiconductor manufacturing factory. There is no limitation in the type of the resist film formed on the wafer W by the wafer processing system 1. For example, the resist film is made of a metal oxide resist (MOR), and the wafer processing system 1 is configured to be particularly useful for forming this MOR resist film. This MOR is a negative resist that contains, for example, tin (Sn) as a metal. Here, containing a metal means containing the metal as a constituent component, and does not mean containing the metal as an impurity. In the following description, unless otherwise mentioned, a resist film is assumed to be made of MOR.

The above MOR reacts with an appropriate amount of water or oxygen after it is applied to the wafer W and before it undergoes a pre-exposure heating process (PAB: Pre Apply Bake), causing a condensation reaction to take place. In this reaction, some of ligands coordinated to the metal are dissociated, enabling the metals contained in the MOR to bond to each other via oxygen. That is, an appropriate amount of metal oxide is generated. Here, the PAB is a processing described above as the pre-bake, and the resist film is cured by the PAB. The cured resist film is less susceptible to the condensation reaction caused by the water and the oxidizing gas.

The resist film after being subjected to the PAB experiences further dissociation of the ligands due to, for example, exposure by the exposure device, turned into a state in which hydroxyl groups are bonded to the metal in place of the ligands. Then, by a heating process (PEB: Post Exposure Bake) described above as the post-exposure bake, these hydroxyl groups undergo dehydration condensation, forming even more bonds between the metals via oxygen, and the exposed portion of the resist film becomes insoluble during a developing process.

If the resist film is exposed to an atmosphere with a relatively high oxygen concentration or a relatively high humidity before it is cured by the PAB, an unnecessary reaction may progress, causing an excessive number of ligands to be dissociated from the metal. If such unnecessary reactions occur, the above-described reactions during the exposure and the PEB may not proceed normally, and as a result, a line width (critical dimension (CD)) of a resist pattern may deviate from a required value, or hardness thereof may decrease. In order to suppress such problems, the wafer processing system 1 is configured to be able to adjust processing spaces in respective processing vessels for performing the formation of the resist film and the PAB and a wafer transfer area that connects these processing spaces into a low-oxygen-concentration and low-humidity atmosphere.

When forming such a low-oxygen-concentration and low-humidity atmosphere, it is assumed to evacuate the processing spaces and the wafer transfer area to create a vacuum atmosphere. If the wafer W is transferred and processed in such a state where the processing spaces and the wafer transfer area are under the vacuum atmosphere, a load lock module for transferring the wafer W between an area including these processing spaces and the wafer transfer area and other areas of the system needs to be provided in the wafer processing system 1. Since the transfer of the wafer W through this load lock module requires time to change the internal pressure of the load lock module in which the wafer W is stored, there is a risk that the efficiency of carrying the wafer W into/from the resist film forming device and the heat treating device for the PAB may degrade. If the efficiency of the carry-in/out is reduced in this way, there is a risk that the processing efficiency (throughput) of the wafers W in the resist film forming device and the heat treating device for the PAB, and besides, in the wafer processing system 1, may decrease.

### [Atmosphere Adjustment in Adjustment Area]

In the wafer processing system 1, in order to suppress such a decrease in the processing efficiency, after a vacuum atmosphere is created in the processing space inside the processing vessel and the wafer transfer area to achieve a low oxygen concentration and a low humidity, a pressure is increased through the supply of an inert gas. This allows the wafer W to be carried to/from the processing space and the wafer transfer area promptly, suppressing a decrease in the processing efficiency of the wafer W in the resist film forming device and the heat treating device for PAB. Hereinafter, in various exemplary embodiments, the area in which the oxygen concentration, the humidity and the pressure are adjusted by the evacuation and the supply of the inert gas in this way will be referred to as an adjustment area R0. In the first exemplary embodiment, processing spaces 60 and 80 and a wafer transfer area 90 to be described later correspond to this adjustment area R0.

It may be possible to create a low-oxygen-concentration and low-humidity atmosphere with a reduced pressure difference with respect to the ambient atmosphere by carrying out the supply of the inert gas and the evacuation in parallel for the adjustment area R0. In such a case, however, a large amount of inert gas may be included in an exhaust gas, so it will take a long time to create the required atmosphere. In order to create the low-oxygen-concentration and low-humidity atmosphere in a relatively short time, the pressure in the adjustment area R0 is first reduced by evacuation to create the vacuum atmosphere, and then increased by introducing the inert gas.

In the adjustment area R0, the atmosphere with the oxygen concentration, the humidity, and the pressure adjusted through the evacuation and the supply of the inert gas as described above is referred to as a second atmosphere. The second atmosphere has been described above to have a low oxygen concentration and a low humidity. More specifically, the oxygen concentration and the humidity of the second atmosphere are set to be lower than an oxygen concentration and a humidity in a first atmosphere outside the adjustment area R0. The outside of the adjustment area R0 is a transfer area for the wafer W that is connected to the adjustment area R0 in the wafer processing system 1 and through which the wafer W is delivered to/from the adjustment area R0. The wafer transfer area 32 corresponds to the outside of the adjustment area R0. In addition, the outside of the adjustment area R0 may be an external space (for example, a floor space) of the wafer processing system 1, an internal space (for example, a space where the wafer transfer device 22 is provided) of the cassette station 2 or an internal space (for example, a space where the wafer transfer device 41 is provided) of the interface station 4.

The oxygen concentration and the humidity of the second atmosphere are still lower than those of an atmosphere in an area where the cassette C is transferred inside a clean room where the wafer processing system 1 is installed. More specifically, the second atmosphere has an oxygen concentration of 5% or less and a humidity (relative humidity) of 5% or less, for example. Also, the pressure of the second atmosphere is set to be equal to that of the first atmosphere or close to that of the first atmosphere so that the aforementioned load lock module can be omitted. The pressure close to that of the first atmosphere is specifically within ±5 kPa of the pressure of the first atmosphere.

The inside of the clean room in which the wafer processing system 1 is installed is maintained at atmospheric pressure (101.3 kPa) or a pressure close to it. The pressure of the wafer transfer area 32, which is outside the adjustment area R0 in the first atmosphere, may deviate from the pressure of the clean room as gas supply and evacuation are performed to suppress particles from adhering to the wafer W. By installing the wafer processing system 1 in the clean room, however, the pressure of the wafer transfer area 32 is set to the atmospheric pressure or close to the atmospheric pressure. Therefore, the pressure of the first atmosphere described above is, for example, 96.3 kPa to 106.3 kPa.

As described above, in the adjustment area R0, as the evacuation is first performed to a vacuum and then the gas supply is performed, the second atmosphere is created. In order to achieve a sufficiently low oxygen concentration and low humidity, the evacuation is performed to a pressure of, e.g., 10 Torr (1.3 kPa) or less, and then the gas is supplied to raise the pressure. The gas supplied to increase the pressure of the adjustment area R0 in this manner is the inert gas as stated above, and is therefore dry without containing moisture. Here, the expression “without containing moisture” does not mean that the gas does not contain moisture that is inevitably mixed in. Although the kind of the inert gas supplied to the adjustment area R0 is not particularly limited, the present exemplary embodiment will be explained for a case where a N₂ (nitrogen) gas is supplied.

### [Layout of Devices and Wafer Transfer Area]

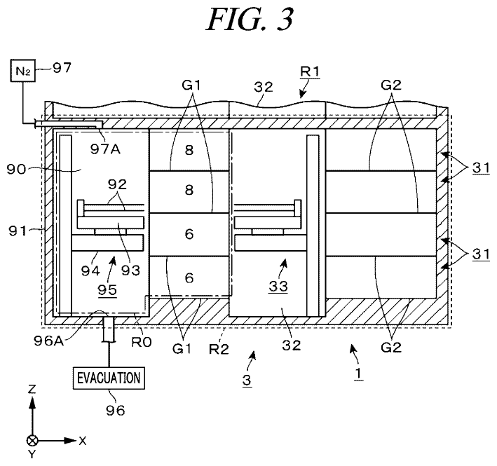

The processing station 3 will be described in further detail with reference to a longitudinal side view of FIG. 3. The processing station 3 has a housing, the inside of which is divided vertically by a partition wall. An area above the partition wall is configured as an upper region R1 in which various devices, such as a heat treating device for PEB and a developing device, for processing the wafer W after being exposed by the exposure device are provided. An area below the partition wall is configured as a lower region R2 in which various devices, such as a resist film forming device and a heat treating device for PAB, for processing the wafer W before being exposed by the exposure device are provided. The above-mentioned multiple layers 31, the wafer transfer area 32, and the wafer transfer device 33 are provided in each of the upper region R1 and the lower region R2, and the upper region R1 and the lower region R2 can transfer the wafers W between the cassette station 2 side and the interface station 4 side.

By regarding the above-mentioned partition wall as a part of the housing, the processing station 3 may be deemed to have two housings respectively forming the upper region R1 and the lower region R2. The housing forming the lower region R2 is referred to as a housing 91 below, and a configuration of this lower region R2 will be explained. As stated above, each layer 31 includes the first block G1 and the second block G2 with the wafer transfer area 32 therebetween, and the processing devices for the wafer W are arranged in these first and second blocks G1 and G2. Therefore, the processing devices are stacked on the front side and the rear side with respect to the wafer transfer area 32. In the first block G1 of each height, the processing devices for processing the wafer W are arranged as described above, and the processing devices are stacked on top of each other. This stacked body of the processing devices is plural in number, and the plurality of stacked bodies are arranged in the Y-axis direction (left-and-right direction). Thus, when viewed from the front, a processing device group arranged in a matrix form is disposed so as to face the wafer transfer area 32. The processing devices constituting this processing device group include a resist film forming device 6 and a heat treating device 8.

A space on the front side of the processing device group is isolated from the surroundings by being enclosed by a part of the housing 91, and is configured as a hermetically sealed wafer transfer area 90. Thus, the processing device group can be seen as being provided so as to partition the lower region R2 into a front region and a rear region. The wafer transfer area 90 has a height extending from the top layer 31 to the bottom layer 31 included in the lower region R2, and a length extending from the leftmost processing device to the rightmost processing device of the processing device group. Thus, the wafer transfer area 90 is formed so as to extend from the front of the respective resist film forming devices 6 to the front of the respective heat treating devices 8.

In the wafer transfer area 90, a wafer transfer device 95 is provided. The wafer transfer device 95 includes a transfer arm 92, a base 93, and a moving mechanism 94. The base 93 is configured to be movable in the Y-axis direction and the Z-axis direction and to be rotatable about a vertical axis by the moving mechanism 94. The transfer arm 92 supports the wafer W and is configured to be able to move the base 93 back and forth.

Each of the resist film forming devices 6 and the heat treating devices 8 is equipped with the aforementioned processing vessel. Transfer ports for the wafer W formed in the respective processing vessels face the wafer transfer area 90, and the wafer W can be transferred from any of the resist film forming devices 6 to any of the heat treating devices 8 by the wafer transfer device 95. The wafer transfer device 33 provided in the wafer transfer area 32 has the same configuration as this wafer transfer device 95.

To create the second atmosphere, an exhaust mechanism 96 and an N₂ gas supply mechanism 97 are connected to the housing 91. The exhaust mechanism 96 is equipped with a vacuum pump, an exhaust line, a valve provided in the exhaust line, and so forth. The exhaust mechanism 96 is capable of switching between evacuating the wafer transfer area 90 and stopping the evacuation through an exhaust port 96A formed in the housing 91, and is also capable of adjusting an evacuation amount by adjusting, for example, the opening degree of the valve. The N₂ gas supply mechanism 97 includes a supply source of an N₂ gas, a pipeline forming a flow path of the N₂ gas, a valve provided in the pipeline, a flow rate control device such as a mass flow controller configured to adjust the flow rate of the N₂ gas supplied to a downstream side of the pipeline. The N₂ gas supply mechanism 97 is capable of switching between supplying the N₂ gas to the wafer transfer area 90 and stopping the supply of the N₂ gas through a gas supply port 97A formed in the housing 91. In addition, an exhaust mechanism other than the exhaust mechanism 96 and an N₂ gas supply mechanism other than the N₂ gas supply mechanism 97 to be described below are assumed to be configured in the same manner as the exhaust mechanism 96 and the N₂ gas supply mechanism 97, for example.

### [Configuration of Resist Film Forming Device]

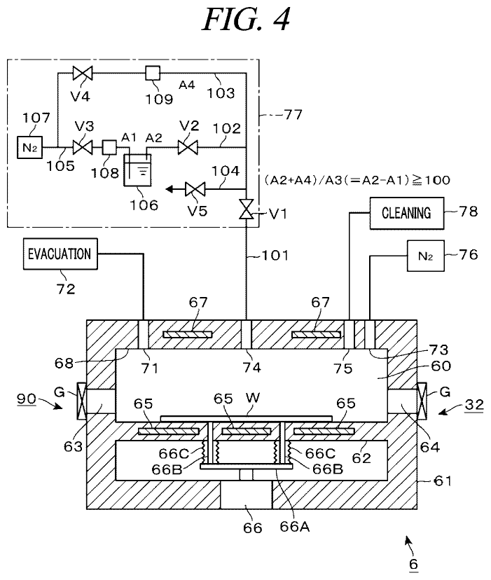

The resist film forming device 6 will be explained with reference to a longitudinal side view of FIG. 4. The resist film forming device 6 forms a resist film by performing CVD (Chemical Vapor Deposition) in the second atmosphere. As described above, the resist film forming device 6 includes a processing vessel 61. A stage 62 is configured to vertically partition this processing vessel 61, which is a single processing vessel, and the wafer W is placed on the stage 62 during film formation. A space above the stage 62 is a processing space 60 for performing the film formation on the wafer W. The processing space 60, which is a single processing space, is circular when viewed from the top, and has a relatively flat structure with a low height so that gas replacement can be performed quickly to suppress particle generation, which will be described later. As will be described later, the resist film forming device 6 is also configured to be capable of performing cleaning to remove the resist film formed on a wall surface forming the processing space 60 by supplying a cleaning gas.

Transfer ports 63 and 64 are formed in sidewalls of the processing vessel 61, and each of them communicates with the processing space 60. The transfer port 63 is open to the wafer transfer area 90 so that the wafer W can be delivered between the wafer transfer device 95 and the resist film forming device 6 as described above. The transfer port 64 is open to the wafer transfer area 32 so that the wafer W can be delivered between the wafer transfer device 33 and the resist film forming device 6 as described above. These transfer ports 63 and 64 are opened and closed by gate valves G. The gate valves G are closed except when necessary for transferring the wafer W, making the processing space 60 airtight.

The stage 62 is configured as a hot plate by embedding a heater 65 therein. The heater 65 heats a top surface of the stage 62 to a preset temperature when film formation on the wafer W and cleaning of the wafer W are performed. A space below the stage 62 is configured as a movement space in which an elevating member 66A is moved up and down by an elevating mechanism 66 provided at a bottom of the processing vessel 61. Further, a power supply line of the heater 65 is drawn out to the outside of the processing vessel 61 through the movement space and connected to a power source. The elevating member 66A is provided with three vertical pins (only two are shown in the drawing) 66B, and the pins 66B are protruded above and retracted below the stage 62, enabling the wafer W to be handed over between the stage 62 and the wafer transfer device 33 (95). A reference numeral 66C in the drawing is a bellows, which surrounds the pins 66B and is connected to the elevating member 66A and the stage 62 to keep the processing space 60 hermetically sealed.

A heater 67 is embedded in an upper wall of the processing vessel 61, and a bottom surface 68 of this upper wall (a ceiling surface forming the processing space 60) is heated to a preset temperature when the film formation on the wafer W and the cleaning of the wafer W are performed. During the film formation, the heater 67 of the upper wall and the heater 65 of the stage 62 provide the wafer W and a gas supplied into the processing space 60 with heat energy required for the film formation. During the cleaning, heat energy required for the cleaning is applied to the resist film attached to the wall surface forming the processing space 60 and a cleaning gas supplied into the processing space 60. In order to facilitate the cleaning, the temperature of the bottom surface 68 of the upper wall of the processing vessel 61 and the temperature of the top surface of the stage 62 are adjusted so that they are higher when the cleaning gas is supplied into the processing space 60 than when a resist component-containing gas is supplied into the processing space 60. The temperature of the bottom surface 68 of the upper wall and the top surface of the stage 62 during the supply of the resist component-containing gas is set to be, e.g., 80° C. to 100° C. The temperature of the bottom surface 68 of the upper wall and the top surface of the stage 62 during the supply of the cleaning gas is, set to be, e.g., 150° C. to 190° C., which is higher than a boiling point of acetic acid constituting the cleaning gas to be described later.

An exhaust port 71 is formed in the bottom surface 68 of the upper wall of the processing vessel 61. An exhaust mechanism 72 is connected to the processing vessel 61, and the processing space 60 can be evacuated through the exhaust port 71 by the exhaust mechanism 72. Also, gas supply ports 73, 74, and 75 are formed in the bottom surface 68 of the upper wall. An N₂ gas supply mechanism 76, a film-forming gas supply mechanism 77, and a cleaning gas supply mechanism 78 are connected to the processing vessel 61, and the N₂ gas supply mechanism 76, the film-forming gas supply mechanism 77, and the cleaning gas supply mechanism 78 are configured to supply gases into the processing space 60 through the gas supply ports 73, 74, and 75, respectively. The N₂ gas supply mechanism 76 and the exhaust mechanism 72 serves to create the second atmosphere in the processing space 60, and constitute an atmosphere adjusting mechanism.

The film-forming gas supply mechanism 77 will be described. The film-forming gas supply mechanism 77 includes pipelines 101 to 105, valves V1 to V5, a storage tank 106, flow rate control devices 108 and 109, and the N₂ gas supply mechanism 107. The storage tank 106 is a storage in which a liquid (film formation source liquid) as a source material for forming the resist film is stored. A downstream end of the pipeline 101 is connected to the upper wall of the processing vessel 61 so that a gas can be introduced into the gas supply port 74. The valve V1 is provided in the pipeline 101, and the pipeline 101 is branched into pipelines 102 and 103 upstream of the valve V1. A pipeline 104 illustrated as being connected to the pipeline 101 in the drawing will be described later.

An upstream side of the pipeline 102 is connected to the storage tank 106 via the valve V2, and an upstream end of the pipeline 102 is open to an atmosphere in the storage tank 106. A downstream end of the pipeline 105 is open within the film formation source liquid stored in the storage tank 106 so that the film formation source liquid can be vaporized by bubbling to generate the resist component-containing gas. An upstream end of the pipeline 105 is connected to the N₂ gas supply mechanism 107 via the flow rate control device 108 and the valve V3 in sequence. An upstream end of the pipeline 103 is connected to an upstream side of the valve V3 in the pipeline 105 via the flow rate control device 109 and the valve V4 in sequence. The flow rate control devices 108 and 109 are, for example, mass flow controllers, and serve to adjust the flow rate of the N₂ gas supplied to the downstream side of the pipelines.

When the valves V2 to V4 are opened, bubbling is performed in the storage tank 106 by the N₂ gas, which is a carrier gas supplied from the N₂ gas supply mechanism 107 into the storage tank 106. As a result, a mixed gas of the resist component-containing gas generated by the vaporization of the film formation source liquid and the N₂ gas as the carrier gas is generated in the storage tank 106 and is supplied into the pipeline 102. This mixed gas from the pipeline 102 and the N₂ gas from the pipeline 103 are respectively supplied into the pipeline 101 to be mixed with each other. When the valve V1 is opened, the gas in the pipeline 101 is supplied into the processing space 60.

That is, the resist component-containing gas generated from the film formation source liquid in the storage tank 106 is supplied into the processing space 60 after being diluted by the carrier gas (N₂ gas) supplied into the pipeline 105 and the N₂ gas supplied into the pipeline 103. Therefore, the N₂ gas supplied as the carrier gas into the pipeline 105 as well as the N₂ gas supplied into the pipeline 103 can also be considered as a dilution gas. The resist component-containing gas is diluted by 100 times or more by these dilution gases. Hereinafter, the gas diluted in this way will be referred to as a film-forming gas for convenience's sake. That is, the film-forming gas is a gas containing the resist component-containing gas and the dilution gas.

The N₂ gas supply mechanism 107 is a rare gas supply mechanism. The storage tank 106 constitutes a mixing section that mixes the resist component-containing gas and the rare gas, and a flow path of the resist component-containing gas in the pipelines 101 and 102 and the storage tank 106 is equipped with such a mixing section that mixes the gases in this way. In addition to constituting the mixing section, the storage tank 106 is also a resist component-containing gas supply section that generates the resist component-containing gas by vaporizing the film formation source liquid, and an upstream end of the pipeline 101 into which the N₂ gas is introduced from the pipeline 103 also corresponds to the mixing section.

Meanwhile, an upstream end of the aforementioned pipeline 104 is connected to the pipeline 101 for supplying a film-forming gas, upstream of the location where the valve V1 is provided. A downstream end of the pipeline 104 is connected via a valve V5 to, for example, an exhaust line of a factory in which the wafer processing system 1 is provided. With the valve V1 closed and the valve V5 opened, the aforementioned film-forming gas is first supplied to the pipeline 104. Thereafter, the valve V5 is closed and the valve V1 is opened, so that the film-forming gas is supplied into the processing space 60. By switching the supply destination in this way, the film-forming gas generated immediately after the start of the bubbling is suppressed from being supplied to the processing space 60, so fluctuations in a dilution ratio of the film-forming gas supplied to the processing space 60 are suppressed.

Diluting the resist component-containing gas by 100 times or more with the rare gas will be described in detail. The pipelines 105 and 102 are respectively provided with flowmeters to measure a flow rate A1 sccm of the carrier gas supplied to the storage tank 106 and a flow rate A2 sccm of the mixed gas of the carrier gas and the resist component-containing gas supplied from the storage tank 106 to the pipeline 102. A flow rate A3 sccm (=flow rate A2 sccm-flow rate A1 sccm) calculated from the measurement values is a flow rate of the resist component-containing gas. The pipeline 103 is also provided with a flowmeter to measure a flow rate A4 sccm of the N₂ gas supplied from the pipeline 103 to the pipeline 101. The total flow rate of the film-forming gas supplied to the processing space 60 via the pipeline 101 is (A2+A4) sccm. The dilution ratio, which is defined as the total flow rate (A2+A4) sccm divided by the flow rate A3 sccm of the resist component-containing gas, is 100 times or more, which means that the aforementioned resist component-containing gas is diluted by 100 times or more. Here, if the dilution of 100 times or more can be achieved with the carrier gas alone, it may not be necessary to supply the N₂ gas to pipeline 101 via the pipeline 103. That is, the aforementioned flow rate A4 sccm may be 0 sccm.

The reason why the dilution ratio of the resist component-containing gas is set to the aforementioned relatively large value will be explained. As stated above, the processing space 60 is set into the second atmosphere with a relatively high pressure equal to or close to the atmospheric pressure during the film formation. If a film-forming gas with a low dilution ratio of the resist component-containing gas is supplied into the processing space 60 with such a high pressure, the partial pressure of the resist component-containing gas in the processing space 60 will be relatively high. In such a high-partial-pressure environment, resist components in the gas may react with each other in the gas phase before being adsorbed onto the wafer W to form a resist film, resulting in particle generation, which may suppressing proper film formation. Therefore, by setting the dilution ratio to a relatively large value of 100 times or more, the partial pressure of the resist component-containing gas in the processing space 60 is set to a relatively low value, and the generation of particles due to the reaction between the resist components described above is suppressed.

The cleaning gas supply mechanism 78 has the same configuration as the film-forming gas supply mechanism 77, except that a source liquid of the cleaning gas is stored in the storage tank 106 instead of the film formation source liquid, and a dilution ratio of the gas generated from this source liquid is different from the dilution ratio of the resist component-containing gas. As described above, the cleaning gas is an acetic acid gas, and the source liquid is, for example, acetic acid. However, the kind of the cleaning gas is not particularly limited as long as it is a gas capable of dissolving and removing the resist film.

### [Configuration of Heat Treating Device for PAB]

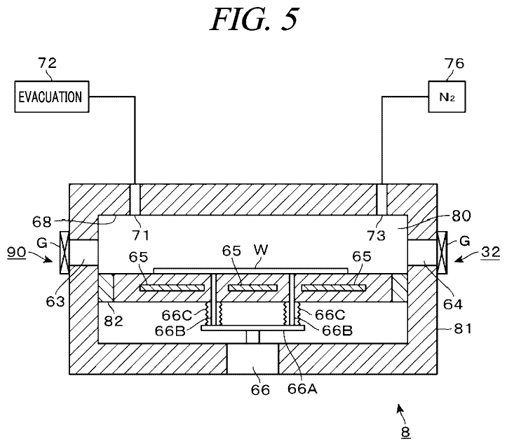

A configuration of the heat treating device 8 for PAB will be explained. Since this heat treating device 8 includes parts configured in the same way as in the resist film forming device 6, the following description will mainly focus on differences from the resist film forming device 6, with reference to a longitudinal side view of FIG. 5. A processing vessel provided in the heat treating device 8 will be referred to as a processing vessel 81. A processing space of this processing vessel 81, which is another processing vessel, is referred to as a processing space 80, and this processing space 80, which is another processing space, has the same configuration as the processing space 60 in the resist film forming device 6. The processing vessel 81, like the processing vessel 61, is formed to face the wafer transfer areas 90 and 32, and is provided with transfer ports 63 and 64 configured to be opened and closed by gate valves G.

In the heat treating device 8, a ring-shaped insulation member 82 is configured to surround the stage 62 in order to set the stage 62 to a relatively high temperature, and the inside of the processing vessel 81 is vertically partitioned by the insulation member 82 and the stage 62, and the processing space 80 is formed above the insulation member 82 and the stage 62. The temperature of the top surface of the stage 62 in the heat treating device 8 is set to a temperature higher than the temperature of the top surface of the stage 62 in the resist film forming device 6 during the supply of the film-forming gas, specifically, a temperature higher than 100° C., for example.

In the shown example, the heater 67 is not provided in an upper wall of the processing vessel 81, but the heater 67 may be provided. This processing vessel 81 is different from the processing vessel 61 of the resist film forming device 6 in that, among the gas supply ports 73 to 75 and the exhaust port 71, only the N₂ gas supply port 73 and the exhaust port 71 are provided in the bottom surface 68 of the upper wall. The exhaust mechanism 72 and the N₂ gas supply mechanism 76 are connected to the processing vessel 81, and the processing space 80 can also be made into the second atmosphere by evacuation through the exhaust port 71 and supply of the N₂ gas through the gas supply port 73.

### [Operations of Respective Devices]

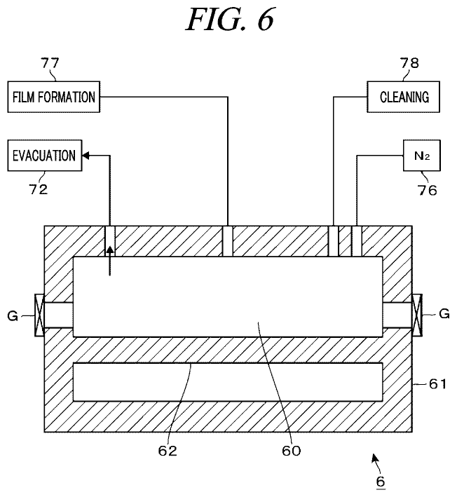

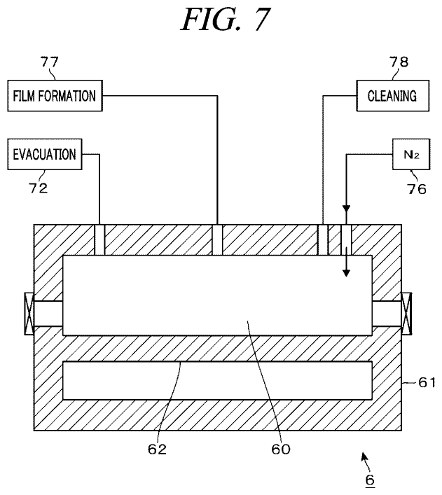

Now, operations of the resist film forming device 6, the heat treating device 8, and the wafer transfer device 95 in performing a transfer of the wafer W and a processing of the wafer W in the wafer processing system 1 will be described in detail. Of these devices, the operation of the resist film forming device 6 will be explained with reference to schematic diagrams of FIG. 6 to FIG. 9. The processing space 60 of the resist film forming device 6 starts to be evacuated by the exhaust mechanism 72 (time t1, FIG. 6) before the wafer W is transferred, so that a vacuum atmosphere is created. Once the processing space 60 reaches the aforementioned preset pressure (time t2), the evacuation by the exhaust mechanism 72 is stopped, and supply of the N₂ gas by the N₂ gas supply mechanism 76 is begun (FIG. 7). Thereafter, the pressure increase is completed and the second atmosphere is achieved (time t3). After the time t3, the evacuation by the exhaust mechanism 72 is resumed, and the evacuation by the exhaust mechanism 72 and the supply of the N₂ gas by the N₂ gas supply mechanism 76 are performed in parallel, so that the second atmosphere is maintained. In this way, the second atmosphere is formed in the processing space 60 before a film forming process on the wafer W is started.

In the processing space 80 of the heat treating device 8 and the wafer transfer area 90, the evacuation by the exhaust mechanisms 72 and 96 and the supply of the N₂ gas by the N₂ gas supply mechanisms 76 and 97 are performed in sequence before the wafer W is transferred, just like in the processing space 60, to thereby create the second atmosphere in the processing space 80 and the transfer area 90. Then, after the second atmosphere is formed, the evacuation and the supply of the N₂ gas are performed in parallel, so that the created second atmosphere is maintained.

In the resist film forming device 6, the top surface of the stage 62 and the bottom surface 68 of the upper wall of the processing vessel 61 are adjusted by the heaters 65 and 67 to a preset temperature within the above-specified range for film deposition. In the heat treating device 8, the top surface of the stage 62 is adjusted to a preset temperature within the aforementioned range by the heater 65.

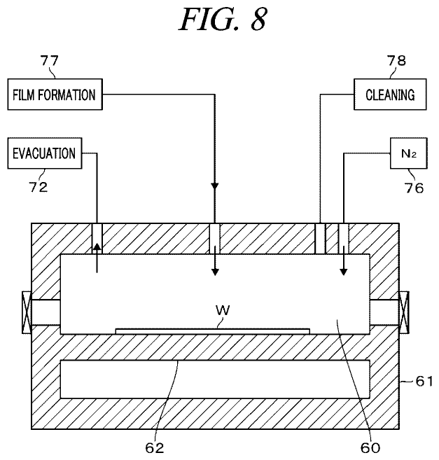

The wafer W is transferred from the cassette C to the wafer transfer area 32, and the gate valve G of the processing vessel 61 of the resist film forming device 6 on the wafer transfer area 32 side is opened. The wafer W is then transferred by the wafer transfer device 33 into the processing space 60 and placed on the stage 62 to be heated to the same temperature as the top surface of the stage 62. The film-forming gas is supplied from the film-forming gas supply mechanism 77 into the processing space 60 which is kept in a hermetically sealed state by closing the gate valve G, and a resist film is formed on a front surface of the wafer W while the processing space 60 is kept in the second atmosphere (FIG. 8). Since the processing space 60 is in the second atmosphere, i.e., under the low oxygen concentration and the low humidity described above, the film formation on the wafer W proceeds while an unnecessary reaction of the resist film is suppressed.

When the resist film on the front surface of the wafer W reaches a required thickness, the supply of the film-forming gas into the processing space 60 is stopped, the gate valve G of the processing vessel 61 on the wafer transfer area 90 side is opened, and the wafer W is taken out of the processing space 60 into the wafer transfer area 90 by the wafer transfer device 95. Then, the gate valve G of the processing vessel 81 of the heat treating device 8 on the wafer transfer area 90 side is opened, and the wafer W is transferred into the processing space 80 of the processing vessel 81. Since the wafer transfer area 90 and the processing space 80 are under the second atmosphere, an unnecessary reaction of the resist film is suppressed during this transfer as well.

Then, the wafer W is placed on the stage 62 and heated, and PAB is performed. The gate valve G is closed to make the processing space 80 airtight, and the PAB proceeds with the processing space 80 maintained in the second atmosphere. Thereafter, the gate valve G of the processing vessel 81 on the wafer transfer area 32 side is opened, and the wafer W is taken out from the processing space 80 of the second atmosphere into the wafer transfer area 32 by the wafer transfer device 33. The wafer W thus taken out to the wafer transfer area 32 is transferred in the wafer processing system 1 to be subjected to the various processes described above to be performed after the PAB, such as exposure, PEB, and development, and is then returned back into the cassette C.

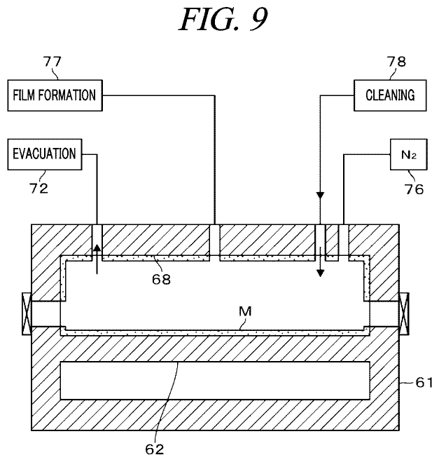

The resist film forming device 6 from which the wafer W has been taken out is in a state where a resist film M is formed on a wall surface forming the processing space 60. In this resist film forming device 6, the top surface of the stage 62 and the bottom surface 68 of the upper wall of the processing vessel 61 are adjusted by the heaters 65 and 67 to a preset temperature within the above-specified range for cleaning. Then, the processing space 60 is evacuated by the exhaust mechanism 72, and the cleaning gas is supplied into the processing space 60 by the cleaning gas supply mechanism 78 (FIG. 9), so that the resist film M formed on the wall surface is dissolved, and the dissolved material is removed by being exhausted. Thereafter, the supply of the cleaning gas to the processing space 60 is stopped, and the cleaning is completed.

If the atmosphere of the processing space 60 is changed from the second atmosphere due to the cleaning process, the second atmosphere is created again by performing the evacuation and the supply of the N₂ gas as described in FIG. 6 and FIG. 7, and then, the wafer W is carried in and processed. As for the frequency of the cleaning, the cleaning is not limited to being performed each time a single sheet of wafer W is processed in the resist film forming device 6, but may be performed each time a certain multiple number of wafers W are processed.

As described above, the processing spaces 60 and 80 and the wafer transfer area 90, which constitute the adjustment area R0 that forms the transfer path from when the wafer W is transferred from the wafer transfer area 32 until the wafer W is returned back to the wafer transfer area 32 after being subjected to the formation of the resist film and the PAB, are set to be in the second atmosphere, and a pressure difference with respect to the first atmosphere of the wafer transfer area 32 is suppressed. As a result, when transferring the wafer W between the wafer transfer area 32 and the processing spaces 60 and 80, stagnation of the wafer W does not occur, unlike in the case of adopting the aforementioned configuration in which the load lock module is provided, so that the transfer of the wafer W can be performed promptly. Likewise, the transfer of the wafer W in the adjustment area R0 (the transfer of the wafer W between the processing spaces 60 and 80 and the wafer transfer area 90) can also be performed quickly without suffering stagnation of the wafer W. This suppresses degradation of the processing efficiency of the resist film formation and the PAB treatment, so that the throughput of the wafer processing system 1 can be made relatively high.

In the above description in conjunction with FIG. 6 and FIG. 7, during the period from the time t1 to the time t3 when the second atmosphere is formed in the processing space 60 of the resist film forming device 6, only one of the evacuation and the supply of the N₂ gas is performed. However, the exemplary embodiment is not limited thereto. To elaborate, in order to suppress the time required to form the second atmosphere from being lengthened as a result of the N₂ gas being exhausted together with water and oxygen in the processing space 60 as described above, the N₂ gas is supplied into the processing space 60 at a first flow rate from the time t1 to the time t2, and, then, from the time t2 to the time t3, the N₂ gas is supplied into the processing space 60 at a second flow rate higher than the first flow rate. In FIG. 6, this first flow rate has been described as being zero (0), but it may be higher than 0.

Furthermore, in order to quickly increase the internal pressure of the processing space 60 from the time t2 to the time t3, the processing space 60 is evacuated at a first exhaust rate from the time t1 to the time t2, and, then, from the time t2 to the time t3, the evacuation is performed at a second exhaust rate lower than the first exhaust rate. In FIG. 7, this second exhaust rate has been described as being zero (0), but it is not limited to 0. Likewise, when forming the second atmosphere in the processing space 80 of the heat treating device 8 and the wafer transfer area 90, the exemplary embodiment is not limited to performing only one of the evacuation and the supply of the N₂ gas, the same as in the processing space 60.

### [First Modification Example of Resist Film Forming Device]

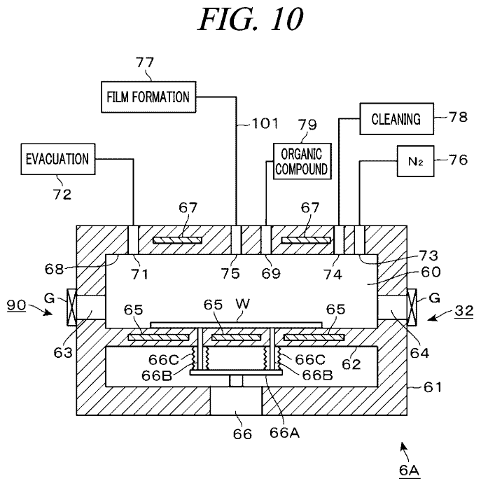

FIG. 10 presents a longitudinal side view of a resist film forming device 6A, which is a first modification example of the resist film forming device. The resist film forming device 6A is different from the resist film forming device 6 in that an organic compound gas supply mechanism 79 is connected to the processing vessel 61. The organic compound gas supply mechanism 79 has the same configuration as the cleaning gas supply mechanism 78 and the film-forming gas supply mechanism 77, except that, for example, an organic compound in the form of a liquid is stored in the storage tank 106, and a gas containing the vaporized organic compound is supplied into the processing space 60 through a gas supply port 69 provided in the bottom surface 68 of the upper wall of the processing vessel 61. There is no particular restriction on the organic compound as long as it can be supplied to the wafer W in the form of a gas and can form a part of the resist film M.

Configured in the same way as the film-forming gas supply mechanism 77, the organic compound gas supply mechanism 79 supplies a mixed gas of the vaporized organic compound and a rare gas into the processing space 60. In the following description, a flow rate of an organic compound gas refers to a flow rate of the vaporized organic compound in the mixed gas, and is calculated in the same way as the flow rate of the resist component-containing gas in the film-forming gas described above.

In the resist film forming device 6A, the film-forming gas is supplied into the processing space 60, which is set into the second atmosphere as in the resist film forming device 6, to form a film on the wafer W by CVD. During this film formation by the CVD, by changing, for example, the flow rate of the carrier gas to change a vaporization efficiency, a flow rate ratio with respect to the resist component-containing gas and the organic compound gas supplied into the processing space 60 is changed.

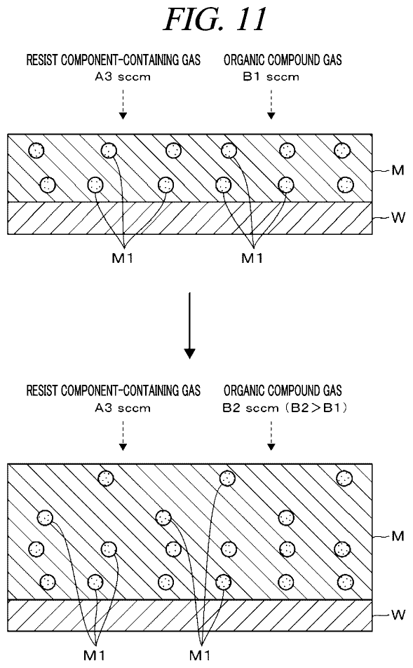

This will be explained in further detail with reference to a schematic longitudinal side view of the wafer W in FIG. 11. The supply of the film-forming gas and the organic compound gas to the processing space 60 is started. The flow rate of the resist component-containing gas contained in the film-forming gas is assumed to be A3 sccm, and the flow rate of the organic compound gas is assumed to be B1 sccm. Upon the lapse of a preset time from the start of the supply of the respective gases, the flow rate of the organic compound gas is changed to B2 sccm, which is higher than B1 sccm, while maintaining the flow rate of the resist component-containing gas at A3 sccm, and the film formation is carried on. After a predetermined time passes by from when the flow rate has been changed, the supply of the film-forming gas and the organic compound gas into the processing space 60 is stopped. As a result, in the resist film M formed on the wafer W, the content ratio of a metal M1 per unit volume in an upper portion of the resist film M is made lower than that in a lower portion thereof, as illustrated in FIG. 11.

Further, instead of increasing the flow rate of the organic compound gas relative to the flow rate of the resist component-containing gas as described above, the flow rate of the resist component-containing gas may be decreased relative to the flow rate of the organic compound gas to set the content ratio of the metal M1 to be different between the upper portion and the lower portion of the resist film M as stated above.

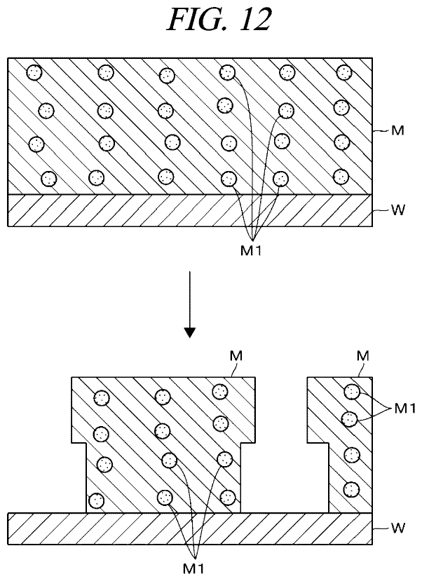

The reason for varying the content ratio of the metal M1 in the resist film in this way will be explained with reference to FIG. 12 and FIG. 13, which provide schematic longitudinal side views of the wafer W to be developed. The upper diagram of FIG. 12 schematically illustrates the wafer W before being developed in a case where the content ratio of the metal M1 contained in the resist film is the same between the upper portion and the lower portion of the resist film M. When this resist film M is exposed in the exposure device, light is difficult to supply to the lower portion of the resist film M than to the upper portion thereof. Therefore, during the exposure, a reaction in the resist film M progresses more in the upper portion, where bonding of the metals M1 via oxygen is accelerated. As a result, during the development, a dissolution reaction of the resist film M progresses more in the lower portion than in the upper portion of the resist film M, so that a formed resist pattern may have a narrow opening width at an upper portion thereof than at a lower portion thereof, as shown in the lower diagram of FIG. 12.

However, if the resist film M is formed so that the content ratio of the metal M1 is lower in the upper portion than in the lower portion thereof as shown in FIG. 11, the reaction in the upper portion may be suppressed during the exposure, and the amount of the metal bonded together via the oxygen becomes more uniform between the upper and lower portions of the resist film M. As a result, during the development, the degree of progress of the dissolution reaction becomes uniform between the upper and lower portions of the resist film M, and the opening width of the resist pattern can be made uniform at the upper and lower portions of the resist film, as shown in FIG. 13, which is desirable.

### [First Modification Example of Heat Treating Device]

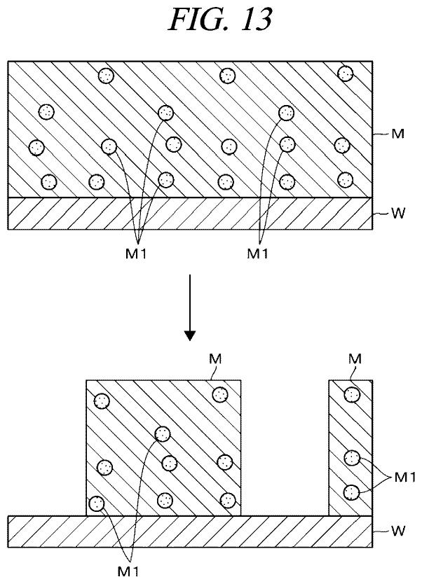

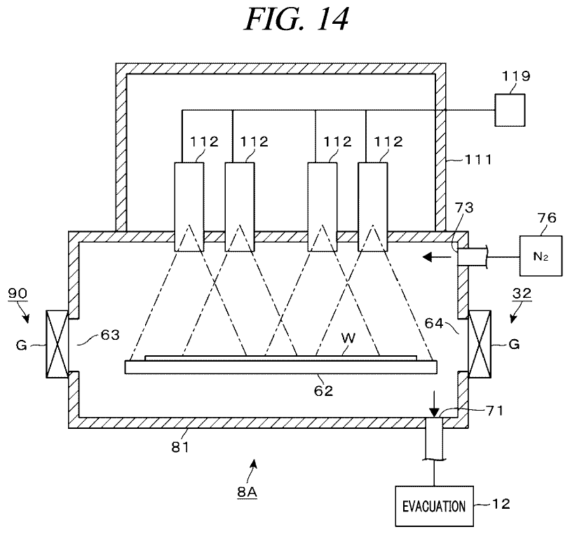

FIG. 14 is a longitudinal side view of a heat treating device 8A, which is a first modification example of the heat treating device for PAB, and the following description of the heat treating device 8A will mainly focus on differences from the heat treating device 8. The side of the stage 62 in the heat treating device 8A is distanced apart from a sidewall of the processing vessel 81. As the wafer transfer devices 33 and 95 are moved up and down, the wafer W can be delivered between the wafer transfer devices 33 and 95 and the stage 62.

In the heat treating device 8A, a light radiation module 111 is provided instead of the heater 65 of the stage 62, and the wafer W is heated by this light radiation module 111. The light radiation module 111 includes a plurality of light sources 112, each of which is composed of, for example, an LED. Each light source 112 is connected to a power supply 119 configured to supply power to the light source 112, and the intensity of the light radiated from the light source 112 can be changed by adjusting the amount of the power supplied from the power supply 119. The light sources 112 and the power supply 119 are configured as a light radiation section. The light radiation module 111 is provided on the processing vessel 81, and the light sources 112 are disposed at the upper wall of the processing vessel 81. The light radiated downwards from the light source 112 (shown by a dashed dotted line in the drawing) is supplied to the wafer W on the stage 62.

The same as in the heat treating device 8, the processing space 80 of the heat treating device 8A is set into the second atmosphere before the wafer W is carried in. Then, after the wafer W is transferred into the processing space 80 of the second atmosphere and placed on, for example, the stage 62, the light radiation from the light source 112 is started, so that PAB is performed on the wafer W. In the shown example, the exhaust port 71 and the N₂ gas supply port 73 for creating the second atmosphere are open to a side surface and a bottom surface of the processing vessel 81, respectively. As stated above, the PAB performed in the second atmosphere is not limited to being performed by placing the wafer W on a hot plate.

### [Second Modification Example of Resist Film Forming Device]

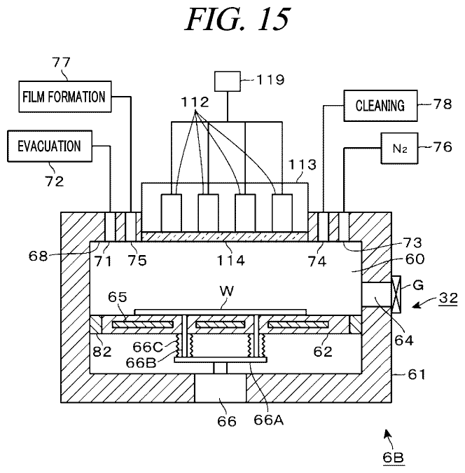

FIG. 15 is a longitudinal side view of a resist film forming device 6B, which is a second modification example of the resist film forming device. The resist film forming device 6B is configured to perform the same film forming process as that performed in the resist film forming device 6 and PAB by light radiation on the wafer W. Thus, the film forming process and the PAB are performed on the wafer W in the same processing space 60.

The resist film forming device 6B is different from the resist film forming device 6 in that it includes a light radiation module 113. The light radiation module 113 has substantially the same configuration as the light radiation module 111 described in FIG. 14, and includes a window 114 in addition to the light sources 112. The window 114 forms a part of the upper wall of the processing vessel 61, and the light from the light sources 112 passes through the window 114 to be supplied to the wafer W placed on the stage 62. The gas supply ports 73 to 75 and the exhaust port 71 are opened in the bottom surface of the upper wall of the processing vessel 61, at locations that do not overlap with the window 114. Further, no heater 67 is provided in the upper wall of this processing vessel 61, and heating of the upper wall in a cleaning process is carried out by, for example, the light radiation module 111 through the light radiation, instead of the heater 67.

Other differences from the resist film forming device 6 are as follows. In the resist film forming device 6B, the wafer W is set to a relatively high temperature to perform PAB, so the stage 62 also reaches a relatively high temperature. For the reason, the stage 62 is enclosed by the insulation member 82, the same as the stage 62 in the heat treating device 8 shown in FIG. 5. Also, when a processing is performed in this resist film forming device 6B, there is no need to transfer the wafer W from this resist film forming device 6B to the wafer transfer area 90, so the processing vessel 61 of the resist film forming device 6B is not provided with the transfer port 63 that are open to the wafer transfer area 90.

A processing sequence for the wafer W in the resist film forming device 6B will be explained. First, the processing space 60 is set into the second atmosphere, and the wafer W is transferred from the wafer transfer area 32 to the processing space 60 by the wafer transfer device 33. The wafer W is then placed on the stage 62 and heated, and the film-forming gas is started to be supplied into the processing space 60 (time t11). The temperature of the wafer W during this film formation is set to be equal to the temperature of the wafer W described above in the film formation in the resist film forming device 6.

Upon the lapse of a preset time after the supply of the film-forming gas is begun, the supply of the film-forming gas is stopped to end the film forming process (time t12), and the light radiation to the wafer W on the stage 62 from the light radiation module 113 is started. As the wafer W is irradiated with light in this way and, also, receives heat from the heater 65 of the stage 62, the temperature of the wafer W increases to the same temperature as the temperature of the wafer W during the heating in the heat treating device 8, so that PAB is performed. Upon the lapse of a predetermined time after the light radiation is begun, the light radiation is stopped to end the PAB (time t13), and the temperature of the wafer W decreases. Thereafter, the wafer W is carried out from the processing vessel 61 into the wafer transfer area 32 by the wafer transfer device 33. The processing space 60 is maintained in the second atmosphere during the period from when the wafer W is carried in until the wafer W is carried out, and the above-described series of processes are performed in the second atmosphere.

In this resist film forming device 6B, the light radiation module 113 is used to raise the temperature of the wafer W for the PAB, it is not required to raise the temperature of the heater 65 of the stage 62. Therefore, after the PAB, there is no need to provide a time period for lowering the temperature of the top surface of the stage 62 to a preset temperature for the film formation, or this time period can be made relatively short. Accordingly, the next wafer W can be placed on the stage 62 and the film forming process can be resumed promptly. Therefore, the resist film forming device 6B equipped with the light radiation module 113 is desirable in terms of increasing the throughput of the wafer processing system 1. However, this does not mean that it is prohibited to perform the PAB by raising the temperature of the heater 65 after the supply of the film-forming gas is completed.

As stated so far, a resist film forming device is provided with a heating mechanism for heating the wafer W. In the resist film forming device 6, the heater 65 corresponds to the heating mechanism, and in the resist film forming device 6B, the heater 65 and the light radiation module 113 correspond to the heating mechanism. This heating mechanism of the resist film forming device may be provided in the resist film forming device and used to perform film formation and PAB, as described in the example of the resist film forming device 6B, or may be used only to perform film formation, as described in the example of the resist film forming device 6. When this heating mechanism is used only for film formation, a heating mechanism for PAB may be provided at a location different from the resist film forming device to heat the wafer W, as described in the example of the heater 65 of the heat treating device 8.

Further, in the resist film forming device 6B, the light radiation by the light radiation module 113 to the wafer W is started after the supply of the film-forming gas into the processing space 60 is stopped, but the light radiation may be started while the film-forming gas is being supplied into the processing space 60. By way of example, the wafer W may be irradiated with light at a first intensity while the film-forming gas is being supplied into the processing space 60, and after the supply of the film-forming gas is stopped, the wafer W may be irradiated with light at a second intensity, which is higher than the first intensity, for PAB.

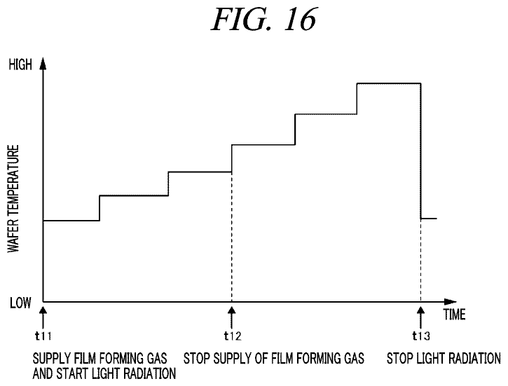

Furthermore, after the supply of the film-forming gas is started, the light intensity may be increased in multiple stages. As a result, as shown in FIG. 16, the temperature of the wafer W may be increased in multiple stages during the period from the time t11 when the supply of the film-forming gas is begun to the time t12 when the supply of the film-forming gas is stopped, and, also, the temperature of the wafer W may be raised in multiple stages during the period from the time t12 when the supply of the film-forming gas is stopped to the time when the light radiation by the light radiation module 113 is stopped to end the PAB. In the case of increasing the temperature of the wafer W during the supply of the film-forming gas as in the example shown in FIG. 16, the energy applied to the wafer W is increased, and the reaction efficiency (i.e., film formation efficiency) between the wafer W and the resist component-containing gas is increased during the supply of the film-forming gas, which results in reduction in the supply time of the film-forming gas. In addition, by increasing the temperature of the wafer W even after the supply of the film-forming gas is stopped, as shown in FIG. 16, the PAB can be completed promptly. Here, however, the light intensity is not limited to being increased in stages as described above. Alternatively, the light intensity may be increased gradually so that the light intensity is proportional to the time elapsed from the beginning of the light radiation.

### [Second Exemplary Embodiment of Wafer Processing System]

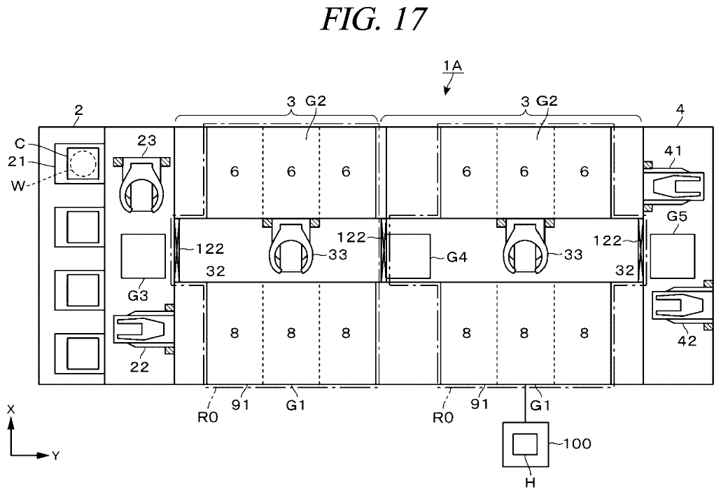

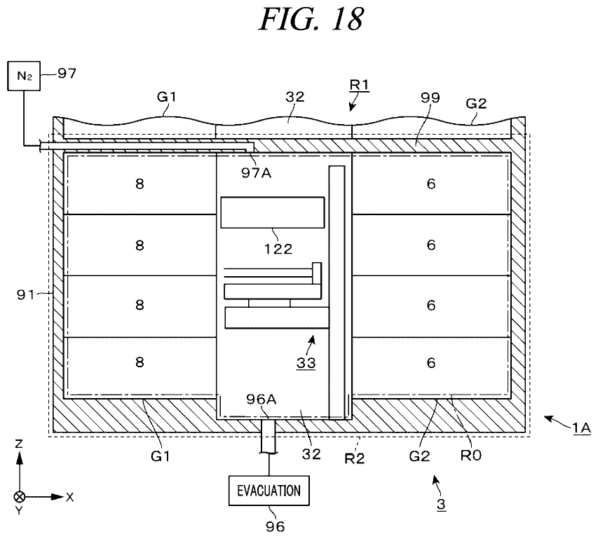

A wafer processing system 1A, which is a wafer processing system according to a second exemplary embodiment, will be explained with reference to a plan view of FIG. 17 and a longitudinal side view of FIG. 18, focusing on its differences from the wafer processing system 1. In the lower region R2 of the processing station 3 of the wafer processing system 1A, the wafer transfer area 90 and the wafer transfer device 95 are not provided. The first block G1 and the second block G2 are provided with the heat treating devices 8 for PAB and the resist film forming devices 6, respectively, and the wafer W processed in the resist film forming device 6 is transferred by the wafer transfer device 33 through the wafer transfer area 32 to the heat treating device 8.

A transfer port for the wafer W is formed in a sidewall of the housing 91 provided in the processing station 3, facing the wafer transfer area 32, and this transfer port for the wafer W is opened and closed by a shutter 122. When the shutter 122 is open, the wafer transfer area 32 communicates with a transfer area for the wafer W in a station adjacent to the processing station 3 in which the wafer transfer area 32 is provided, and the wafer W can be transferred between the wafer transfer area 32 and the transfer area for the wafer W in the adjacent station. When the shutter 122 is closed, the wafer transfer area 32 is isolated from the transfer area for the wafer W in the adjacent station, and is turned into a hermetically sealed space. The shutter 122 is kept closed except when necessary for the transfer of the wafer W.

In addition, in the wafer processing system 1A, the fourth block G4 is disposed in one of the two adjacent processing stations 3 so that the respective wafer transfer areas 32 of the two processing stations 3 are easily separated into the sealed spaces by the housing 91. However, if the respective wafer transfer areas 32 can be separated, the fourth block G4 may be disposed so as to straddle the two processing stations 3, as in the wafer processing system 1 shown in FIG. 1.

The exhaust mechanism 96 and the N₂ gas supply mechanism 97 are connected to the housing 91, and an exhaust port 96A and an N₂ gas supply port 97A are open to the wafer transfer area 32. In the wafer transfer area 32 with the shutter 122 closed, evacuation and supply of the N₂ gas are performed, and the wafer transfer area 32 can be set into the second atmosphere in the same manner as the wafer transfer area 90 in the first exemplary embodiment. Thus, in the wafer processing system 1A, the adjustment area R0 in which the second atmosphere is formed is composed of the wafer transfer area 32, the processing space 60 of the resist film forming device 6, and the processing space 80 of the heat treating device 8. The first atmosphere outside this adjustment area R0 corresponds to the atmosphere of transfer areas for the wafer W in the cassette station 2 and the interface station 4 to which the wafer transfer area 32 is adjacent, and is set to, for example, the same pressure as that of the wafer transfer area 32 described in the first exemplary embodiment.

In this wafer processing system 1A, each of the wafer transfer area 32, the processing space 60 of the resist film forming device 6, and the processing space 80 of the heat treating device 8 is maintained in the second atmosphere until the wafer W is transferred. Then, the wafer W transferred from the cassette station 2 into the wafer transfer area 32 is subjected to film formation in the resist film forming device 6, and is then transferred via the wafer transfer area 32 to the heat treating device 8 to undergo PAB, and then sent to the interface station 4.

In the above-described wafer processing system 1A as well, a place, such as a load lock module, for changing pressure in the course of transferring the wafer W from the cassette station 2 to the interface station 4 does not need to be provided, so there occurs no stagnation in the transfer of the wafer W at that place. Therefore, the same as in the wafer processing system 1, the wafer processing system 1A may feature high processing efficiency.

### [Third Exemplary Embodiment of Wafer Processing System]

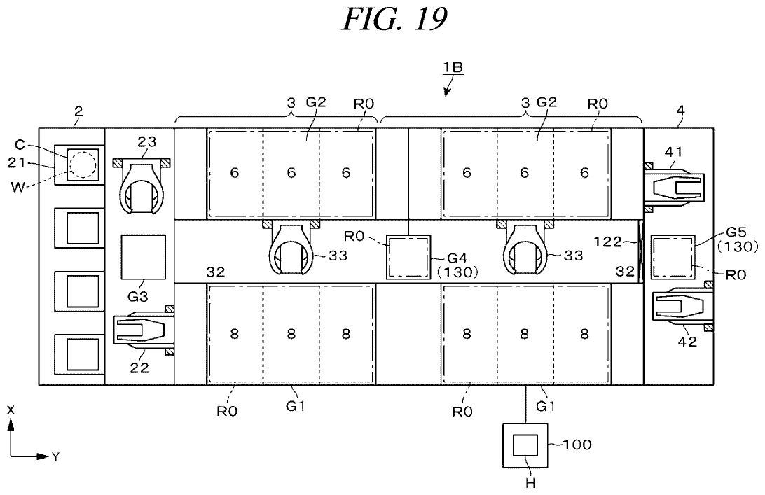

A wafer processing system 1B, which is a wafer processing system according to a third exemplary embodiment, will be explained with reference to a plan view of FIG. 19. This wafer processing system 1B has substantially the same configuration as the wafer processing system 1A according to the second exemplary embodiment, and in the lower region R2 of the processing station 3, the heat treating devices 8 and the resist film forming devices 6 are provided in the first block G1 and the second block G2, respectively. However, in the wafer transfer area 32 of this lower region R2, the second atmosphere is not formed, and the wafer transfer area 32 may be set into, for example, an atmospheric atmosphere of an atmospheric pressure or a pressure close thereto.

In this wafer processing system 1B, a buffer device 130 is provided in each of the fourth block G4 and the fifth block G5, which are accessible by the wafer transfer device 33 in the wafer transfer area 32 of the lower region R2. The buffer device 130 can store a multiple number of wafers W in an internal sealed space thereof, and can set this sealed space into the second atmosphere. Thus, in this wafer processing system 1B, the adjustment area R0 in which the second atmosphere is formed is composed of the inside of the buffer device 130, the processing space 60 of the resist film forming device 6, and the processing space 80 of the heat treating device 8. The wafer transfer area 32, which is connected to each of the inside of the buffer device 130, the processing space 60 of the resist film forming device 6, and the processing space 80 of the heat treating device 8, is located outside the adjustment area R0, and the atmosphere of this wafer transfer area 32 corresponds to the first atmosphere.

In the wafer processing system 1B, the wafer W that has been subjected to film formation in the resist film forming device 6 is transferred to the buffer device 130 via the wafer transfer area 32, and then transferred from the buffer device 130 to the heat treating device 8 via the wafer transfer area 32 to be subjected to PAB. The inside of the buffer device 130 forms a part of a transfer area for transferring the wafer W from the resist film forming device 6 to the heat treating device 8.

The transfer of the wafer W through the buffer device 130 will be explained in further detail. In some occasions, a wafer W transferred to the buffer device 130 (hereinafter, referred to as a succeeding wafer W) cannot be transferred to the heat treating device 8 because a wafer W (referred to as a preceding wafer W) is being carried into the heat treating device 8, for example. In such a case, the succeeding wafer W is made to stand by in the buffer device 130 until the preceding wafer W is carried out from the heat treating device 8 so that it can be transferred to the heat treating device 8, and after standing by, the succeeding wafer W is transferred to the heat treating device 8. By transferring the wafers in this way, it is possible to suppress the time during which the succeeding wafer W is exposed to an atmosphere different from the second atmosphere, during the time period from the formation of the resist film to the PAB, so that reaction of the resist film with water and oxygen is suppressed.

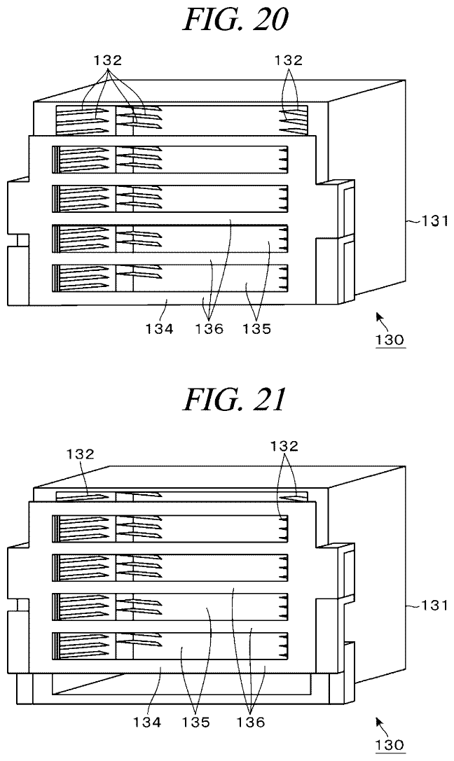

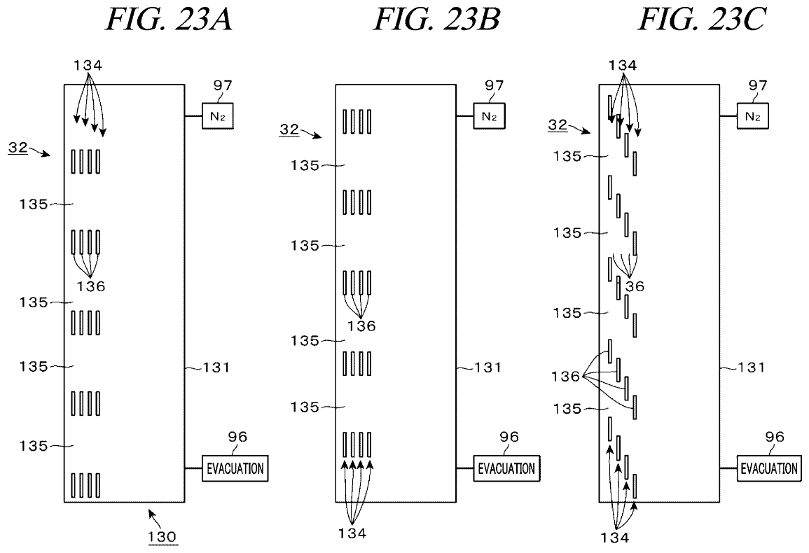

A configuration example of the buffer device 130 will be explained with reference to perspective views of FIG. 20 to FIG. 22 and schematic longitudinal side views of FIG. 23A to FIG. 23C. The buffer device 130 has a rectangular housing 131 with one of four sidewalls thereof removed. The inside of the housing 131 can be made into a hermetically sealed space as stated above by using a shutter 134 provided in place of the removed sidewall. In the following explanation of the buffer device 130, the side from which the sidewall has been removed will be referred to as a front side. This front side faces the wafer transfer area 32 so that the wafer W can be transferred by the wafer transfer device 33.

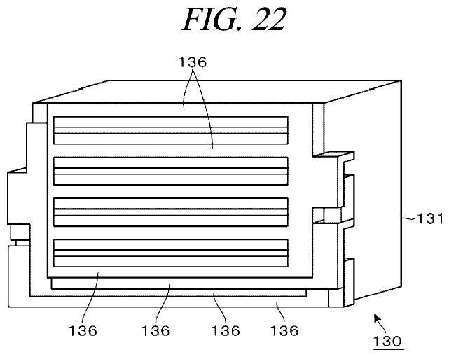

Supports 132 for supporting the wafer W are provided in multiple levels on the sidewalls of the housing 131, and every four supports 132 at the same height form a single group to support a periphery of a rear surface of one sheet of wafer W to allow the wafer W to stand by. This standby area for the wafer W formed by the supports 132 belonging to the same group is called a slot. The shutter 134 includes four shutters 134 arranged on the front side of the housing 131 so that their positions in a front-to-rear direction are different from each other. Each shutter 134 is provided with four horizontally elongated through holes 135 that are arranged vertically. Portions of the shutter 134 located above or below the through holes 135 are called bridge portions 136. Each shutter 134 can be moved up and down by an elevating mechanism provided in the housing 131. The positions of the bridge portions 136 shown in FIG. 23A, FIG. 23B and FIG. 23C correspond to the positions of the bridge portions 136 in FIG. 20, FIG. 21 and FIG. 22, respectively.

By combining the height positions of the respective shutters 134, it is possible to switch between a state in which some slots are open to the wafer transfer area 32 through the through holes 135 (the states shown in FIG. 20 and FIG. 21) and a state in which the inside of the housing 131 is hermetically sealed and all slots are isolated from the outside of the housing 131 (the state shown in FIG. 22). As shown in FIG. 20 and FIG. 21, the slots that are opened can be changed by changing the height of the respective shutters 134. The inside of the housing 131 is sealed except when necessary for the transfer of the wafer W. The exhaust mechanism 96 and the N₂ gas supply mechanism 97 are connected to the housing 131, and the inside of the housing 131 can be made into the second atmosphere by performing evacuation and supply of the N₂ gas while keeping the housing 131 hermetically sealed. When the wafer W is delivered to the slot, only some of the slots are opened to the wafer transfer area 32, so that the housing 131 can be suppressed from exiting the second atmosphere by this opening operation.

As in the wafer processing system 1B described above, the entire area through which the wafer W is transferred, from the resist film forming device 6 to the heat treating device 8, does not have to be in the second atmosphere, and only a part thereof may be set into the second atmosphere to suppress a reaction of the resist film with water and oxygen. By setting only the part to be in the second atmosphere in this way, enlargement of the area where the N₂ gas is supplied and exhausted can be suppressed, so that the manufacturing cost and operating cost of the wafer processing system can be reduced. However, in order to more reliably suppress the reaction of the resist film, it is desirable to set the entire area through which the wafer W is transferred, from the resist film forming device 6 to the heat treating device 8, to be in the second atmosphere, the same as in the wafer processing system 1A.

### [Fourth Exemplary Embodiment of Wafer Processing System]

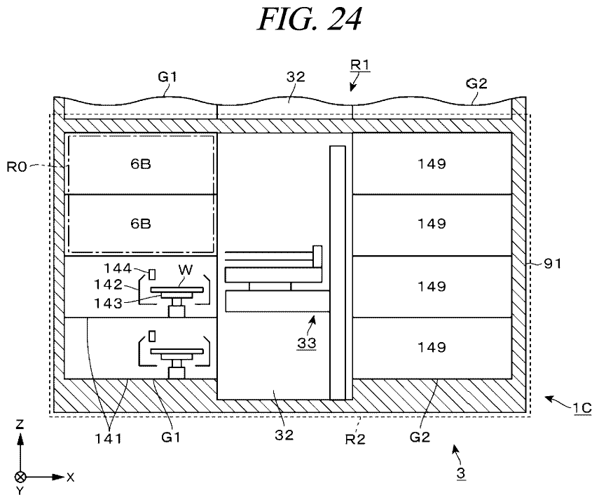

A wafer processing system 1C, which is a wafer processing system according to a fourth exemplary embodiment, will be explained, focusing on differences from the wafer processing system 1B. FIG. 24 is a longitudinal side view of the lower region R2 in the processing station 3 of this wafer processing system 1C. In the first block G1 of this lower region R2, the resist film forming device 6B capable of performing PAB as explained in FIG. 15, and a resist film removing device 141 configured to perform a processing called edge bead removal (EBR) are stacked on top of each other.

The resist film removing device 141 includes a cup 142 for accommodating the wafer W, a stage 143 configured to be rotatable inside the cup 142 while attracting and holding the wafer W, and a nozzle 144 configured to be movable inside and outside the cup 142. The nozzle 144 supplies thinner, which is a liquid, to a peripheral portion of the wafer W placed and being rotated on the stage 143, so that the resist film is removed. Due to performing this liquid processing, it is difficult to form a vacuum atmosphere, so the second atmosphere is not formed in the resist film removing device 141.

The second block G2 is provided with a heat treating device 149. The heat treating device 149 is a heat plate (the stage 62 equipped with the heater 65) on which the wafer W is placed, the same as in the heat treating device 8 described in FIG. 5, or is equipped with the light radiation module 111 described in FIG. 14 and is configured to heat the wafer W by radiating light to the wafer W on the stage 62. The wafer W is transferred by the wafer transfer device 33 to the resist film forming device 6B, the resist film removing device 141, and the heat treating device 149 in this order to be processed. PAB is performed in each of the resist film forming device 6B and the heat treating device 149. That is, the PAB is performed before and after the EBR.

Since the heat treating device 149, which is a device configured to perform a heat treatment after film removal, heats the wafer W processed in the resist film removing device 141, the second atmosphere is not formed in this heat treating device 149, either, as in the resist film removing device 141. In this wafer processing system 1C, the adjustment area R0 in which the second atmosphere is created is the processing space 60 of the resist film forming device 6B, and the first atmosphere is the atmosphere of the wafer transfer area 32 connected to this adjustment area R0.

If hardening of the resist film progresses due to the progress of the PAB, it becomes difficult for the resist film to dissolve in the thinner. For this reason, the PAB is performed in two stages before and after the EBR, as mentioned above. In the PAB before the EBR (referred to as pre-stage PAB) performed in the resist film forming device 6B, the reactivity of the resist film to water and oxygen is reduced, while hardening of the resist film is controlled so as to ensure the solubility of the resist film in the thinner. In the PAB after the EBR (referred to as post-stage PAB) performed in the heat treating device 149 as a post-heating process, the wafer W is heated to harden the resist film sufficiently so that the reactivity to the water and oxygen is further reduced. In order to allow proper hardening of the resist film in the respective stages, the heating time or temperature of the wafer W in the post-stage PAB performed by the heat treating device 149 is set to be longer or higher than that in the pre-stage PAB performed by the resist film forming device 6B.

The setting in which the heating time of the wafer W in the post-stage PAB is longer than that in the pre-stage PAB will be described in further detail. A start point of the heating time of the wafer W in the resist film forming device 6B, which performs the pre-stage PAB and a film forming process, is a time point when the supply of the film-forming gas into the processing space 60 is stopped so the film forming process is ended. An end point of the heating time of the wafer W in the resist film forming device 6B is a time point when the wafer W is distanced away from the stage 62 and is no longer heated by the heater 65 of the stage 62, or no longer heated by the light radiation.

A start point of the heating time of the wafer W in the heat treating device 149, which performs the post-stage PAB, is a time point when the wafer W is placed on the stage 62 and heating by the heater 65 of the stage 62 is started, or when heating by the light radiation from the light radiation module 111 is started. If the heat treating device 149 is equipped with both the stage 62 with the heater 65 and the light radiation module 111, a start point of heating is the earlier of the start point of the heating by the stage 62 and the start point of the heating by the light radiation. An end point of the heating time in the heat treating device 149 is a time point when neither the heating by the placement on the stage 62 nor the heating by the light radiation is performed, just like the end point of the heating time in the resist film forming device 6B.

The setting in which the heating temperature of the wafer W in the post-stage PAB is higher than that in the pre-stage PAB. This heating temperature is the temperature of the wafer W during the above-described heating time. If the temperature of the wafer W during the heating time varies as a result of a varying output of the light radiation module or the heater, the maximum temperatures would be compared. That is, assuming that the maximum temperature during the heating time is X° C. in the pre-stage PAB and the maximum temperature during the heating time is Y° C. in the post-stage PAB, when X is lower than Y (X<Y), the heating temperature of the wafer W in the post-stage PAB is said to be higher than that in the pre-stage PAB.

In the above-described wafer processing system 1C, the resist film forming device 6B is provided, so the pre-stage PAB, which is performed in the second atmosphere, is performed in the same processing vessel as used in the film forming process. However, the exemplary embodiment is not limited to performing the pre-stage PAB and the film forming process in the same processing vessel. By way of example, after the film forming process is performed on the wafer W in the resist film forming device as described in the first to third exemplary embodiments, the wafer W may be transferred to a heat treating device located at a different location from the resist film forming device, and the pre-stage heating may be performed in that heat treating device. That is, by providing the resist film removing device 141 and the heat treating device 149 for heating after EBR in the first to third exemplary embodiments as well, the heating of the wafer W in the second atmosphere described above may be performed as the pre-stage PAB, and the EBR and the post-stage PAB may be performed after the pre-stage PAB. In such a case where the wafer is transferred to a processing vessel other than the processing vessel in which the film forming process is performed and the pre-stage PAB is performed in that processing vessel, a start point of the heating time of the pre-stage PAB may be a time point when the wafer W is placed on a heat plate inside the processing vessel to which the wafer W has been transferred, or a time point when heating by light radiation is started, whichever is earlier.

### [Fifth Exemplary Embodiment of Wafer Processing System]

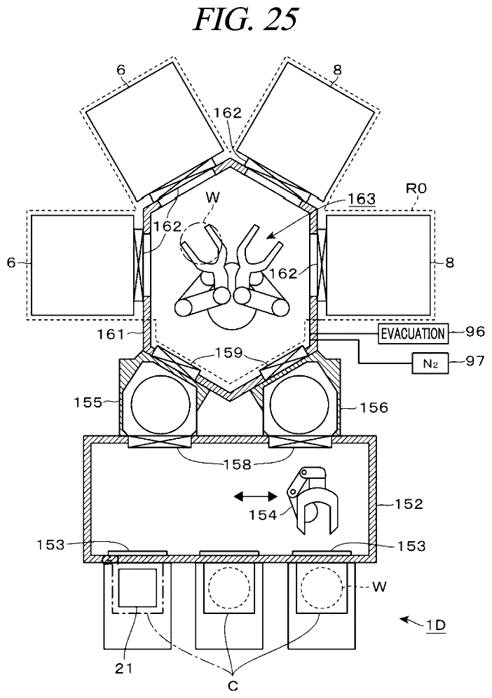

Now, a wafer processing system 1D, which is a wafer processing system according to a fifth exemplary embodiment, will be explained with reference to a plan view of FIG. 25, focusing on differences from the wafer processing systems 1, 1A to 1C described above. The wafer processing system 1D includes a pre-stage transfer chamber 152, and multiple cassette placement tables 21 are arranged in a left-and-right direction in front of the pre-stage transfer chamber 152. A sidewall of the pre-stage transfer chamber 152 is provided with doors 153, which can be used to attach or detach lids of the cassettes C on the cassette placement tables 21. The pre-stage transfer chamber 152 is equipped with a first transfer device 154, which is a multi-joint arm configured to be movable up and down. The first transfer device 154 is capable of transferring the wafer W between the cassette C on the cassette placement tables 21 and relay chambers 155 and 156 to be described later.

In the pre-stage transfer chamber 152, on the opposite side (rear side) of the cassette placement table 21, the relay chambers 155 and 156 are arranged side by side, and a post-stage transfer chamber 161 is disposed at the rear of the relay chambers 155 and 156. Gate valves 158 are provided between the relay chambers 155 and 156 and the pre-stage transfer chamber 152, and gate valves 159 are provided between the relay chambers 155 and 156 and the post-stage transfer chamber 161. Each of the relay chambers 155 and 156 is equipped with a placement table on which a wafer W is placed, and the placement table is equipped with pins configured to be protruded above and retracted below a top surface of the placement table to raise or lower the wafer W so that the wafer W can be transferred to/from the first transfer device 154 and a second transfer device 163 to be described below.

Two resist film forming devices 6 and two heat treating devices 8 are connected to the post-stage transfer chamber 161 via respective gate valves 162, and these resist film forming devices 6 and heat treating devices 8 are arranged to surround the post-stage transfer chamber 161 when viewed from the top. The post-stage transfer chamber 161 is provided with a second transfer device 163 implemented by a multi-joint arm, which enables the wafer W to be transferred to/from the resist film forming device 6, heat treating device 8, and the relay chambers 155 and 156. The gate valves 158, 159, and 162 are kept closed except when necessary to transfer the wafer W, thereby isolating the respective modules.

When the gate valves 159 and 162 are closed, the post-stage transfer chamber 161 forms an airtight space. The exhaust mechanism 96 and the N₂ gas supply mechanism 97 are connected to the post-stage transfer chamber 161, and the inside of the post-stage transfer chamber 161 is set into the second atmosphere. In this wafer processing system 1D, the post-stage transfer chamber 161, the processing space 60 of the resist film forming device 6, and the processing space 80 of the heat treating device 8 form the adjustment area R0 in which the second atmosphere is created. The relay chambers 155 and 156 connected to the post-stage transfer chamber 161 are outside the adjustment area R0, and the atmosphere of the relay chambers 155 and 156 is the first atmosphere.

In this wafer processing system 1D, the wafer W carried out from the cassette C is transferred in the order of the pre-stage transfer chamber 152→relay chamber 155→post-stage transfer chamber 161→resist film forming device 6→post-stage transfer chamber 161→heat treating device 8→post-stage transfer chamber 161→relay chamber 156→pre-stage transfer chamber 152, and then returned back to the cassette C. By transferring the wafer W in this way, the wafer W undergoes resist film formation and PAB in the same manner as in the wafer processing system 1, and the atmosphere around the wafer W is maintained in the second atmosphere from the resist film forming process through the PAB process. In the wafer processing system 1D, stagnation in the transfer of the wafer W can be suppressed, and high throughput can be achieved, the same as in the wafer processing systems 1 and 1A to 1C.

### [Other Configurations]

In each of the wafer processing systems described above, the layout of the respective devices is not limited to the examples described above but may be modified in various ways. By way of example, the stacking number of the devices for processing the wafers W and the order of stacking them can be changed appropriately. The number of the stacked bodies, each of which is formed of the devices stacked on top of each other, arranged along the Y-axis direction (left-and-right direction) is not particularly limited to the shown examples. In addition, the devices described above as being provided in the first block G1 may be provided in the second block G2, and the devices described above as being provided in the second block G2 may be provided in the first block G1. In the drawings, such as FIG. 3, etc., illustrating the processing station 3, although the arrangement of the above-described devices other than the resist film forming device and the heat treating device is not clearly shown, they may be provided in the first block G1 and the second block G2 appropriately.

In addition, in the wafer processing systems 1, 1A to 1C, the formation of the resist film, the PAB, and the transfer of the wafer W under the second atmosphere are performed in the lower region R2 of the processing station 3. However, these processes and the transfer may be performed in the upper region R1 instead. That is, the upper region R1 may be set as a region where the wafer W before exposure is processed, and the lower region R2 may be set as a region where the wafer W after exposure is processed. Also, the upper region R1 may not be provided in the wafer processing systems 1, 1A to 1C. That is, in these wafer processing systems 1, 1A to 1C, only the resist film formation and the PAB may be performed on the wafer W before the wafer W is returned back to the cassette C after being carried out from the cassette C, the same as in the wafer processing system 1D. In such a configuration where only the pre-exposure processes are performed, the interface station 4 may not be provided, and the wafer W finished with the processing in the processing station 3 may be returned from the cassette station 2 to the cassette C.

Furthermore, the locations and number of the exhaust ports and the N₂ gas supply ports that are open to the processing devices and the transfer areas to create the second atmosphere are not limited to the examples described above, and may be modified in various ways. However, in the resist film forming device, if the resist component-containing gas remains in the processing space 60 for a long time, particle generation may be facilitated due to a reaction between the gases. In order to suppress particle generation by increasing gas replacement efficiency in the processing space 60 after the completion of the film formation and thus suppressing the resist component-containing gas from remaining in the processing space 60 for a long time, the wall surface forming the processing space 60 has no irregularities or uneven portions other than the gas supply ports 73 to 75 and the exhaust port 71.

In order to supply the gases into the processing space 60 with high uniformity, a shower head may be provided at a ceiling of the processing vessel 61, and the gases supplied from the gas supply ports 73 to 75 may be supplied into the processing space 60 from supply openings of this shower head. That is, there may be adopted a configuration in which the shower head forms a part of the wall surface forming the processing space 60, and discharge openings of the shower head face the processing space 60.

As explained in FIG. 13, when forming, on the wafer W, the resist film with different content ratios of the metal M1 in its upper and lower portions by using the organic compound gas, the upper portion and the lower portion may be formed in different film forming devices. The supply destination of the organic compound gas is not limited to the processing space 60, but may be a flow path formed by pipelines constituting the film-forming gas supply mechanism 77. That is, the organic compound gas may be supplied to the processing space 60 after being mixed with the film-forming gas or the resist component-containing gas and the rare gas constituting the film formation gas. Further, the way to vaporize the film formation source liquid is not limited to the bubbling. The dilution ratio may be calculated from a flow rate of the mixed gas containing the carrier gas and the resist component-containing gas and a flow rate of the rare gas containing the carrier gas, as in the case of the bubbling described above.

Furthermore, the film formation source liquid in the storage tank 106 of the film-forming gas supply mechanism 77 is not limited to being supplied into the processing space 60 as the resist component-containing gas by being vaporized as described above, but may be supplied into the processing space 60 in the form of mist together with an inert gas such as an N₂ gas. Thus, the resist component-containing gas in the present disclosure includes a liquid containing the resist component in a mist form.

Furthermore, in the above-described various exemplary embodiments, the substrate as a processing target is not limited to the wafer, but may be, by way of non-limiting example, a substrate for manufacturing a flat panel display, or a mask substrate for manufacturing a mask for exposure. Thus, a rectangular substrate may also be processed.

It should be noted that the above-described exemplary embodiments are illustrative in all aspects and are not anyway limiting. The above-described exemplary embodiments may be omitted, replaced, modified and combined in various ways without departing from the scope and the spirit of claims.

According to the exemplary embodiment, it is possible to improve the processing efficiency in forming the resist film on the substrate by a gas treatment.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

We claim:

1. A substrate processing system, comprising:
a first processing vessel forming a first processing space and a second processing vessel forming a second processing space, each of the first processing space and the second processing space being for storing a substrate;
an atmosphere adjuster configured to set an adjustment area including the first processing space and the second processing space into a second atmosphere, the second atmosphere having an oxygen concentration and a humidity lower than an oxygen concentration and a humidity of a first atmosphere at an outside of the adjustment area and having a pressure equal to or close to a pressure of the outside of the adjustment area;
a resist film former comprising the first processing vessel, the resist film former being configured to supply a resist component-containing gas into the first processing space under the second atmosphere to form a resist film on the substrate; and
a heater comprising the second processing vessel, the heater being configured to heat, under the second atmosphere, the substrate before being subjected to exposure of the resist film.

2. The substrate processing system of claim 1, further comprising:
a discharge port open to the first processing space of the first processing vessel to supply the resist component-containing gas into the first processing space;
a flow path connected to the discharge port, the flow path comprising a mixing section in which gases are mixed;
a resist component-containing gas supply configured to supply the resist component-containing gas to the flow path; and
a rare gas supply configured to supply a rear gas to the mixing section to dilute the resist component-containing gas by 100 times or more.

3. The substrate processing system of claim 2, further comprising:
an exhaust configured to evacuate the adjustment area; and
an inert gas supply configured to supply an inert gas to the adjustment area,
wherein before the resist component-containing gas is supplied into the first processing space to form the resist film on the substrate, the evacuation and the supply of the inert gas are performed to create the second atmosphere in the first processing space.

4. The substrate processing system of claim 1,
wherein the adjustment area further includes a transfer area of the substrate between the first processing space and the second processing space.

5. The substrate processing system of claim 1, further comprising:
a cleaning gas supply configured to supply a cleaning gas into the first processing space to remove the resist film inside the first processing vessel, after the resist film is formed by supplying the resist component-containing gas to the substrate.

6. The substrate processing system of claim 1,
wherein the heater comprises a heat plate configured to place and heat the substrate thereon, or a light radiation module configured to radiate light to the substrate to heat the substrate.

7. The substrate processing system of claim 1, further comprising:
a resist film remover configured to remove the resist film on a peripheral portion of the substrate after being heated by the heater; and
a post-removal heater configured to heat the substrate, from which the resist film on the peripheral portion is removed, at a temperature higher than a temperature in the heater or for a heating time longer than a heating time in the heater.

8. The substrate processing system of claim 1, wherein the resist film former further comprises an organic compound gas supply configured to supply an organic compound gas into the first processing space to adjust a metal content ratio in the resist film, such that an upper portion of the resist film has a lower metal content ratio than a lower portion.

9. The substrate processing system of claim 1, wherein the resist film former includes a light radiation module including a plurality of light sources, the light radiation module being configured to perform a pre-apply bake (PAB) on the substrate within the first processing space after forming the resist film, without transferring the substrate to the second processing vessel.

10. The substrate processing system of claim 9, wherein the light radiation module is configured to radiate light at a first intensity during supply of the resist component-containing gas and at a second intensity, higher than the first intensity, during the PAB.

11. The substrate processing system of claim 1, further comprising a buffer configured to store a plurality of substrates in a sealed space maintained in the second atmosphere, the buffer device forming part of the adjustment area and configured to temporarily hold substrates between processing in the first and second processing vessels.

12. The substrate processing system of claim 11, wherein the buffer includes:
a plurality of slots, each slot configured to support a substrate; and
a shutter configured to selectively open specific slots to a transfer area outside the adjustment area while maintaining the second atmosphere in the sealed space.

13. A substrate processing method, comprising:
storing a substrate in a first processing vessel forming a first processing space and a second processing vessel forming a second processing space;
setting, by an atmosphere adjuster, an adjustment area including the first processing space and the second processing space into a second atmosphere, the second atmosphere having an oxygen concentration and a humidity lower than an oxygen concentration and a humidity of a first atmosphere at an outside of the adjustment area and having a pressure equal to or close to a pressure of the outside of the adjustment area;
supplying, in a resist film former comprising the first processing vessel, a resist component-containing gas into the first processing space under the second atmosphere to form a resist film on the substrate; and
heating, in a heater comprising the second processing vessel, the substrate under the second atmosphere.

14. The substrate processing method of claim 13, further comprising:
evacuating the adjustment area to a pressure of 1.3 kPa or less and subsequently supplying an inert gas to create the second atmosphere before forming the resist film; and
supplying a cleaning gas into the first processing space to remove residual resist film after forming the resist film.

15. The substrate processing method of claim 13, further comprising:
supplying an organic compound gas into the first processing space during formation of the resist film to adjust a metal content ratio, such that an upper portion of the resist film has a lower metal content ratio than a lower portion.

16. The substrate processing method of claim 13, further comprising:
performing a pre-apply bake (PAB) in the first processing space using a light radiation module after forming the resist film; and
transferring the substrate to a resist film remover to remove the resist film from a peripheral portion, followed by a post-removal heating at a higher temperature or longer duration than the PAB.

17. The substrate processing method of claim 13, further comprising:
by a heat plate of a heater, heating the substrate thereon.

18. A non-transitory computer-readable recording medium having stored thereon computer-executable instructions stored thereon, which when executed by a processor of a substrate processing system causes the substrate processing system to perform the following substrate processing method:
storing a substrate in a first processing vessel forming a first processing space and a second processing vessel forming a second processing space;
setting, by an atmosphere adjuster, an adjustment area including the first processing space and the second processing space into a second atmosphere, the second atmosphere having an oxygen concentration and a humidity lower than an oxygen concentration and a humidity of a first atmosphere at an outside of the adjustment area and having a pressure equal to or close to a pressure of the outside of the adjustment area;
supplying, in a resist film former comprising the first processing vessel, a resist component-containing gas into the first processing space under the second atmosphere to form a resist film on the substrate; and
heating, in a heater comprising the second processing vessel, the substrate under the second atmosphere.

19. The non-transitory computer-readable recording medium of claim 18, wherein the method further comprises:
evacuating the adjustment area to a pressure of 1.3 kPa or less and subsequently supplying an inert gas to create the second atmosphere before forming the resist film; and
supplying a cleaning gas into the first processing space to remove residual resist film after forming the resist film.

20. The non-transitory computer-readable recording medium of claim 18, wherein the method further comprises:
supplying an organic compound gas into the first processing space during formation of the resist film to adjust a metal content ratio, such that an upper portion of the resist film has a lower metal content ratio than a lower portion;
performing a pre-apply bake (PAB) in the first processing space using a light radiation module after forming the resist film; and
transferring the substrate to a resist film remover to remove the resist film from a peripheral portion, followed by a post-removal heating at a higher temperature or longer duration than the PAB.
